(19) United States
(12) Patent Application Publication
(10) Pub. No.: US 2024/0170266 A1
(43) Pub. Date: May 23, 2024

(54) COMPONENT FOR SEMICONDUCTOR DEVICE FABRICATION APPARATUS, SEMICONDUCTOR DEVICE FABRICATION APPARATUS INCLUDING THE SAME, AND METHOD OF FABRICATING SEMICONDUCTOR DEVICE

(71) Applicant: SK enpulse Co., Ltd., Gyeonggi-do (KR)

(72) Inventors: Hyun Soo LEE, Seoul (KR); Hae Mi KANG, Seoul (KR); Do Hyun CHOI, Seoul (KR); Il Gu YONG, Seoul (KR); Jong Kyu LEE, Seoul (KR); Ho Geun HAN, Seoul (KR); Ju Young SONG, Seoul (KR)

(21) Appl. No.: 18/512,021

(22) Filed: Nov. 17, 2023

(30) Foreign Application Priority Data
Nov. 18, 2022 (KR) 10-2022-0155434
Nov. 18, 2022 (KR) 10-2022-0155435
Nov. 28, 2022 (KR) 10-2022-0161228
Jul. 5, 2023 (KR) 10-2023-0087240

(51) Int. Cl. H01J 37/32; H01L 21/683; H01L 21/687

(52) U.S. Cl. CPC H01J 37/32642; H01J 37/32568; H01J 37/32715; H01L 21/6831; H01L 21/68735; H01J 2237/2007; H01J 2237/334

(57) ABSTRACT

The present invention provides a component for a semiconductor device fabrication apparatus, a semiconductor device fabrication apparatus including the same, and a method of fabricating a semiconductor device, wherein the component includes single-crystal silicon, wherein, on at least one surface thereof, a water contact angle is 45° to 74° and a diiodomethane contact angle is 41° to 57°.

### CROSS-REFERENCE TO RELATED APPLICATIONS

The present application claims priority under 35 U.S.C 119(a) to Korean Patent Application Nos. 10-2022-0155435, filed on Nov. 18, 2022, 10-2022-0155434 filed on Nov. 18, 2022, 10-2022-0161228 filed on Nov. 28, 2022, and 10-2023-0087240 filed on Jul. 5, 2023, which is incorporated herein by reference in its entirety.

### TECHNICAL FIELD

Embodiments of the present disclosure relate to a component for a semiconductor device fabrication apparatus, a semiconductor device fabrication apparatus including the same, and a method of fabricating a semiconductor device.

### BACKGROUND

In general, a semiconductor etching showerhead is a device used to etch a silicon wafer by spraying gas in a plasma state onto the silicon wafer in a semiconductor fabrication chamber.

The showerhead has a plurality of gas injection holes, and gas in a plasma state passes through the gas injection holes.

To precisely etch the wafer, the showerhead holes must be precisely formed.

In the related art document 1 (Korean Patent No. 10-0299975) and the related art document 2 (Korean Patent No. 10-0935418), an abrasive and a silicon disk are placed against a drilling plate on which a plurality of tips protrudes. Then, while supplying the abrasive to the drilling plate and the disk, ultrasonic waves are applied to the drilling plate to drill the disk.

In the related art document 1 and the related art document 2, when processing a thick showerhead, the length of the pin inserted into the drilling plate increases. In this case, the pin vibrates when ultrasonic waves are generated, causing the problem that the holes of the showerhead are not formed uniformly.

In the case of silicon carbide (Sic) containing silicon (Si) and carbon (C) in a ratio of 1:1, due to strong covalent bonds thereof, the silicon carbide (Sic) has high thermal conductivity compared to other ceramic materials and has excellent wear resistance, high-temperature strength, and chemical resistance. Accordingly, the silicon carbide (Sic) is widely applied to reinforce, supplement or replace components that are weak or essential in terms of mechanical properties. In particular, the silicon carbide has a Mohs hardness of 9.2, the second highest after diamond, and is widely used in the field of semiconductor components due to excellent durability thereof.

Therefore, embodiments of the present disclosure have been made to address the above issues, and it is one object of the present disclosure to provide a component capable of efficiently suppressing defects on a semiconductor substrate in a plasma process for fabricating a semiconductor, a semiconductor device fabrication apparatus including the same, and a method of fabricating a semiconductor device.

### SUMMARY

In accordance with an aspect of the present disclosure, provided is a component for a semiconductor device fabrication apparatus including single-crystal silicon, wherein, on at least one surface thereof, a water contact angle is 450 to 740 and a diiodomethane contact angle is 410 to 57°.

In the component for a semiconductor device fabrication apparatus according to one embodiment, a surface free energy of the surface may be 40 mN/m to 65 mN/m.

In the component for a semiconductor device fabrication apparatus according to one embodiment, a dispersion free energy of the surface may be 30 mN/m to 45 mN/m.

In the component for a semiconductor device fabrication apparatus according to one embodiment, a polar free energy of the surface may be 5 mN/m to 25 mN/m.

The component for a semiconductor device fabrication apparatus according to an embodiment of the present disclosure may include a body portion formed to surround a semiconductor substrate; an inclined portion formed to extend from the body portion toward a center of the semiconductor substrate; and a guide portion formed to extend from the inclined portion toward a center of the semiconductor substrate and disposed below the semiconductor substrate, wherein the body portion includes an upper surface; and a lower surface facing the upper surface, wherein, on the upper surface, a water contact angle is 45° to 74° and a diiodomethane contact angle is 41° to 57°.

In the component for a semiconductor device fabrication apparatus according to one embodiment, the inclined portion may include an inclined surface extending from the upper surface in a direction inclined with respect to the upper surface, wherein, on the inclined surface, a water contact angle is 45° to 74° and a diiodomethane contact angle is 41° to 57°.

In the component for a semiconductor device fabrication apparatus according to one embodiment, the guide portion may include a guide surface extending from the inclined surface, wherein, on the guide surface, a water contact angle is 45° to 74° and a diiodomethane contact angle is 41° to 57°.

In the component for a semiconductor device fabrication apparatus according to one embodiment, on 70% or more of the total surface, a water contact angle may be 45° to 74° and a diiodomethane contact angle may be 41° to 57°.

In the component for a semiconductor device fabrication apparatus according to one embodiment, the body portion, the inclined portion, and the guide portion may be integrally formed of single-crystal silicon.

In the component for a semiconductor device fabrication apparatus according to one embodiment, a surface free energy of the upper surface may be 40 mN/m to 65 mN/m.

The component for a semiconductor device fabrication apparatus according to one embodiment may include an upper surface; a lower surface facing the upper surface; and through-holes formed to penetrate from the upper surface to the lower surface, wherein, on the lower surface, a water contact angle is 45° to 74° and a diiodomethane contact angle is 41° to 57°.

In accordance with another aspect of the present disclosure, provided is a semiconductor device fabrication apparatus including a chamber for accommodating a semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein, on at least one surface of the focus ring or upper electrode, a water contact angle is 45° to 74° and a diiodomethane contact angle is 41° to 57°.

In accordance with still another aspect of the present disclosure, provided is a method of fabricating a semiconductor device, the method including an operation of placing a semiconductor substrate on a semiconductor device fabrication apparatus; and an operation of treating the semiconductor substrate, wherein the semiconductor device fabrication apparatus includes a chamber for accommodating the semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein, on at least one surface of the upper electrode and focus ring, a water contact angle is 45° to 74° and a diiodomethane contact angle is 41° to 57°.

The component for a semiconductor device fabrication apparatus according to an embodiment may include single-crystal silicon, wherein an Si—OH ratio on at least one surface thereof is 0.16 to 0.28, wherein the Si—OH ratio is a value obtained by dividing an area of an Si—OH peak by an area of an Si single-crystal peak in a Raman spectrum of the surface, the Si single-crystal peak is a peak at a Raman shift of 520 cm⁻¹ to 522 cm⁻¹ in the Raman spectrum of the surface, and the Si—OH peak is a peak at a Raman shift of 940 cm⁻¹ to 980 cm⁻¹ in the Raman spectrum of the surface.

In the component for a semiconductor device fabrication apparatus according to one embodiment, on the surface, a dopant ratio may be less than 0.12, wherein the dopant ratio is a value obtained by dividing an area of a dopant peak by an area of an Si single-crystal peak in a Raman spectrum of the surface, and the dopant peak is a peak intensity at a Raman shift of 303 cm⁻¹ to 305 cm⁻¹ in the Raman spectrum of the surface.

In the component for a semiconductor device fabrication apparatus according to one embodiment, on the surface, a body-centered cubic ratio may be less than 0.01, wherein the body-centered cubic ratio is a value obtained by dividing an area of a body-centered cubic peak by an area of an Si single-crystal peak in a Raman spectrum of the surface, and the body-centered cubic peak is a peak at a Raman shift of 433 cm⁻¹ to 435 cm⁻¹ in the Raman spectrum of the surface.

In the component for a semiconductor device fabrication apparatus according to one embodiment, on the surface, a rhombohedral ratio may be less than 0.01, wherein the rhombohedral ratio is a value obtained by dividing an area of a rhombohedral peak by an area of an Si single-crystal peak in a Raman spectrum of the surface, and the rhombohedral peak is a peak at a Raman shift of 348 cm⁻¹ to 350 cm⁻¹ in the Raman spectrum of the surface.

The component for a semiconductor device fabrication apparatus according to one embodiment may include a body portion formed to surround a semiconductor substrate; an inclined portion formed to extend from the body portion toward a center of the semiconductor substrate; and a guide portion formed to extend from the inclined portion toward a center of the semiconductor substrate and disposed below the semiconductor substrate, wherein the body portion includes an upper surface; and a lower surface facing the upper surface, wherein on the upper surface, an Si—OH ratio is 0.16 to 0.28.

In one embodiment, the Si—OH ratio may be 0.17 to 0.28.

In one embodiment, the Si—OH ratio may be 0.18 to 0.28.

In one embodiment, on 70% or more of the total surface, an Si—OH ratio may be 0.16 to 0.28.

In one embodiment, the body portion, the inclined portion, and the guide portion may be integrally formed of single-crystal silicon.

A method of manufacturing the component for a semiconductor device fabrication apparatus according to an embodiment may include an operation of cutting a silicon ingot to obtain a silicon plate; an operation of cutting the silicon plate to obtain an unprocessed component; an operation of processing one surface of the unprocessed component; and an operation of treating at least one surface of the processed component so that an Si—OH ratio on the treated surface is adjusted to 0.16 to 0.28, wherein the Si—OH ratio is a value obtained by dividing an area of an Si—OH peak by an area of an Si single-crystal peak in a Raman spectrum of the surface, the Si single-crystal peak is a peak at a Raman shift of 520 cm⁻¹ to 522 cm⁻¹ in the Raman spectrum of the surface, and the Si—OH peak is a peak at a Raman shift of 940 cm⁻¹ to 980 cm⁻¹ in the Raman spectrum of the surface.

In one embodiment, the operation of treating at least one surface of the processed component may include an operation of irradiating the surface with light in a gas atmosphere containing oxygen.

The semiconductor device fabrication apparatus according to an embodiment of the present disclosure may include a chamber for accommodating a semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein the upper electrode or the focus ring includes single-crystal silicon, wherein, on at least one surface of the upper electrode or focus ring, an Si—OH ratio is 0.16 to 0.28, wherein the Si—OH ratio is a value obtained by dividing an area of an Si—OH peak by an area of an Si single-crystal peak in a Raman spectrum of the surface, the Si single-crystal peak is a peak at a Raman shift of 520 cm⁻¹ to 522 cm⁻¹ in the Raman spectrum of the surface, and the Si—OH peak is a peak at a Raman shift of 940 cm⁻¹ to 980 cm⁻¹ in the Raman spectrum of the surface.

The method of fabricating a semiconductor device according to an embodiment of the present disclosure may include an operation of placing a semiconductor substrate on a semiconductor device fabrication apparatus; and an operation of treating the semiconductor substrate, wherein the semiconductor device fabrication apparatus includes a chamber for accommodating the semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein the upper electrode or the focus ring includes single-crystal silicon, wherein, on at least one surface of the upper electrode or focus ring, an Si—OH ratio is 0.16 to 0.28, wherein the Si—OH ratio is a value obtained by dividing an area of an Si—OH peak by an area of an Si single-crystal peak in a Raman spectrum of the surface, the Si single-crystal peak is a peak at a Raman shift of 520 cm⁻¹ to 522 cm⁻¹ in the Raman spectrum of the surface, and the Si—OH peak is a peak at a Raman shift of 940 cm⁻¹ to 980 cm⁻¹ in the Raman spectrum of the surface.

The focus ring according to an embodiment may include a body portion formed to surround a semiconductor substrate; and a guide portion placed inside the body portion and below the semiconductor substrate, wherein the body portion includes an upper surface; and a lower surface facing the upper surface, wherein, on the upper surface, a first reduced peak valley roughness is 0.005 μm to 2 μm, wherein the first reduced peak valley roughness is a sum of a first Spk roughness of the upper surface and a first Svk roughness of the upper surface.

The focus ring according to an embodiment may further include an inclined portion formed to extend from the body portion to the guide portion, wherein the inclined portion includes an inclined surface extending from the upper surface in a direction inclined with respect to the upper surface, wherein, on the inclined surface, a second reduced peak valley roughness is 0.005 μm to 2 μm, wherein the second reduced peak valley roughness is a sum of a second Spk roughness of the inclined surface and a second Svk roughness of the inclined surface.

In the focus ring according to one embodiment, the guide portion may include a guide surface extending from the inclined surface to the bottom of the semiconductor substrate, wherein, on the guide surface, a third reduced peak valley roughness is 0.5 μm to 2 μm, wherein the third reduced peak valley roughness is a sum of a third Spk roughness of the guide surface and a third Svk roughness of the guide surface.

In the focus ring according to one embodiment, the third Spk roughness may be greater than the first Spk roughness.

In the focus ring according to one embodiment, the third Svk roughness may be greater than the first Svk roughness.

In the focus ring according to one embodiment, on the upper surface, a first Sv roughness may be −3 μm to −0.01 μm, and a first Sp roughness may be 0.01 μm to 4 μm.

In the focus ring according to one embodiment, on the upper surface, a first Spy roughness may be 0.01 μm to 6 μm, and the first Spy roughness may be a sum of an absolute value of the first Sv roughness and an absolute value of the first Sp roughness.

In the focus ring according to one embodiment, on the upper surface, a first Sz roughness may be 0.01 μm to 6 μm.

In the focus ring according to one embodiment, on the upper surface, a first Sk roughness may be 0.005 μm to 3 μm and a first reduced peak valley ratio may be 0.5 to 1.3, wherein the first reduced peak valley ratio is a value obtained by dividing a sum of the first Spk roughness and the first Svk roughness by the first Sk roughness.

In the focus ring according to one embodiment, the body portion, the inclined portion, and the guide portion may be integrally formed of single-crystal silicon.

In the focus ring according to one embodiment, the first Spk roughness may be 0.001 μm to 1 μm, and the first Svk roughness may be 0.002 μm to 1.7 μm.

The semiconductor device fabrication apparatus according to an embodiment of the present disclosure may include a chamber for accommodating a semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein the focus ring includes a body portion formed to surround the semiconductor substrate; and a guide portion placed inside the body portion and below the semiconductor substrate, wherein the body portion includes an upper surface; and a lower surface facing the upper surface, wherein, on the upper surface, a first reduced peak valley roughness is 0.005 μm to approximately 2 μm, and the first reduced peak valley roughness is a sum of a first Spk roughness of the upper surface and a first Svk roughness of the upper surface.

The method of fabricating a semiconductor device may include an operation of placing a semiconductor substrate on a semiconductor device fabrication apparatus; and an operation of treating the semiconductor substrate, wherein the semiconductor device fabrication apparatus includes a chamber for accommodating the semiconductor substrate; an upper electrode that is disposed inside the chamber opposite the semiconductor substrate and sprays a process gas; an electrostatic chuck configured to support the semiconductor substrate and disposed below the semiconductor substrate; and a focus ring formed to surround the semiconductor substrate and provided on the electrostatic chuck, wherein the focus ring includes a body portion formed to surround the semiconductor substrate; and a guide portion placed inside the body portion and below the semiconductor substrate, wherein the body portion includes an upper surface; and a lower surface facing the upper surface, wherein, on the upper surface, a first reduced peak valley roughness is 0.005 μm to approximately 2 μm, and the first reduced peak valley roughness is a sum of a first Spk roughness of the upper surface and a first Svk roughness of the upper surface.

The semiconductor device fabrication apparatus according to an embodiment may be equipped with the component according to an embodiment.

A component for a semiconductor device fabrication apparatus according to an embodiment of the present disclosure includes a surface having a water contact angle of 45° to 74° and a diiodomethane contact angle of 41° to 57°. Since the surface has an appropriate water contact angle and diiodomethane contact angle, the inside of the component for a semiconductor device fabrication apparatus according to an embodiment can be effectively protected from external contamination.

In addition, since the surface of the component for a semiconductor device fabrication apparatus according to an embodiment has a water contact angle and a diiodomethane contact angle within the above-described ranges, external contaminants such as particles can be prevented from attaching to the part.

Accordingly, the component for a semiconductor device fabrication apparatus according to an embodiment can prevent external and internal contamination and prevent contaminants from transferring into the chamber of a semiconductor device fabrication apparatus. Accordingly, the component for a semiconductor device fabrication apparatus according to an embodiment can minimize defects that occur in a semiconductor device fabrication process.

In addition, the surface of the component for a semiconductor device fabrication apparatus according to an embodiment has appropriate surface energy. Accordingly, the component for a semiconductor device fabrication apparatus according to an embodiment has appropriate surface properties and can minimize residues generated during a semiconductor plasma process.

The component for a semiconductor device fabrication apparatus according to an embodiment has a surface having an Si—OH ratio of 0.16 to 0.28. Since the surface contains an appropriate amount of Si—OH, the inside of the component for a semiconductor device fabrication apparatus according to an embodiment can be effectively protected from external contamination.

In addition, since the surface of the component for a semiconductor device fabrication apparatus according to an embodiment contains Si—OH within the above-described range, external contaminants such as particles can be prevented from adhering to the part.

Accordingly, the component for a semiconductor device fabrication apparatus according to an embodiment can prevent external and internal contamination and prevent contaminants from transferring into the chamber of a semiconductor device fabrication apparatus. Accordingly, the component for a semiconductor device fabrication apparatus according to an embodiment can minimize defects occurred during a semiconductor substrate fabrication process.

In addition, the surface of the component for a semiconductor device fabrication apparatus according to an embodiment has an appropriate dopant peak. Accordingly, the component for a semiconductor device fabrication apparatus according to an embodiment has appropriate electrical properties and can minimize defects which occur from the dopant.

In addition, the component for a semiconductor device fabrication apparatus according to an embodiment has a surface having a low body-centered cubic ratio and a low rhombohedral ratio. Accordingly, the frequency of crystal defects on the surface of the component for a semiconductor device fabrication apparatus according to an embodiment can be low.

Accordingly, in a process of fabricating a semiconductor substrate, the component for a semiconductor device fabrication apparatus according to an embodiment can prevent excessive wear caused by the crystal defects. Accordingly, the component for a semiconductor device fabrication apparatus according to an embodiment can suppress generation of particles in a process chamber due to excessive wear. Accordingly, the component for a semiconductor device fabrication apparatus according to an embodiment can prevent defects which occur in a process of fabricating a semiconductor substrate. In addition, since excessive wear is suppressed, the component for a semiconductor device fabrication apparatus according to an embodiment can have improved durability.

A focus ring according to an embodiment includes appropriate reduced peak valley roughness. An upper electrode and focus ring according to an embodiment can have a surface including a micro-mountain having an appropriate height and a micro-valley having an appropriate depth.

Since the focus ring according to an embodiment includes a surface having an appropriate surface uneven shape, the focus ring can improve plasma flowability on the surface. Accordingly, the focus ring can efficiently guide plasma to the semiconductor substrate.

Accordingly, a semiconductor device fabrication apparatus including the focus ring according to an embodiment can effectively process the surface of the semiconductor substrate.

In addition, since the focus ring according to an embodiment includes a surface having an appropriate surface uneven shape, the focus ring can prevent process residues from being deposited. That is, since the focus ring according to an embodiment has appropriate reduced peak valley roughness, the focus ring can have appropriate irregularities. Accordingly, the contact area between the surface of the focus ring according to an embodiment and process residues can be low. Accordingly, although the process residues are temporarily attached to the surface of the focus ring according to an embodiment, the process residues can be easily detached.

Since the focus ring according to an embodiment includes a surface having a repeating shape of a micro-mountain having an appropriate height and a micro-valley having an appropriate depth, the focus ring can improve plasma flowability and inhibit attachment of process residues.

Accordingly, when a plasma process such as a plasma etching process is performed, defects caused by particles generated from the surface of the focus ring according to an embodiment of the present disclosure can be easily suppressed. That is, since the focus ring according to an embodiment has an appropriate surface shape, defects that occur when a portion of the micro-mountain of the focus ring falls off can be prevented.

These and other features and advantages of the invention will become apparent from the detailed description of embodiments of the present disclosure and the following figures.

### DESCRIPTION OF DRAWINGS

FIG. 1 illustrates an upper electrode according to an embodiment of the present disclosure.

FIG. 2 is a cross-sectional view of an upper electrode according to an embodiment of the present disclosure.

FIG. 3 is a cross-sectional view of an upper electrode according to another embodiment of the present disclosure.

FIG. 4 is a perspective view of a focus ring according to an embodiment of the present disclosure.

FIG. 5 is a cross-sectional view of a focus ring according to an embodiment of the present disclosure.

FIG. 6 is a diagram for describing a semiconductor device fabrication apparatus according to an embodiment of the present disclosure.

FIG. 7 is a cross-sectional view of a plasma region-confined assembly according to an embodiment of the present disclosure.

FIG. 8 is the Raman spectrum of the upper surface of a focus ring according to Example 7.

### DETAILED DESCRIPTION

In the description of elements, it should be understood that when an element or layer is referred to as being “on” or “under” another element or layer, the element or layer can be directly on another element or layer or on intervening elements or layers, and the criteria for “on” and “under” will be provided based on the drawings. The size of each component in the drawings may be exaggerated for description and does not indicate the actual size.

An upper electrode according to an embodiment of the present disclosure may be a component used in an apparatus for fabricating a semiconductor device. That is, the upper electrode may be a component that forms a portion of the semiconductor device fabrication apparatus.

The upper electrode may be a component used in a plasma processing apparatus for fabricating a semiconductor device. The upper electrode may be a component used in a plasma etching apparatus for selectively etching a semiconductor substrate.

The upper electrode may be a component of an upper electrode assembly for spraying gas for forming plasma.

In addition, the upper electrode may be a component that forms a portion of an assembly that accommodates a wafer and defines a plasma area.

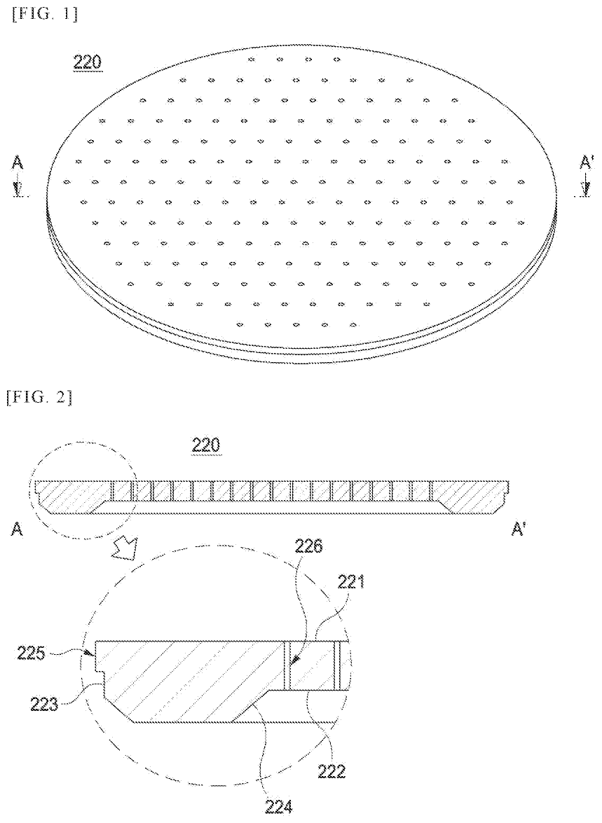

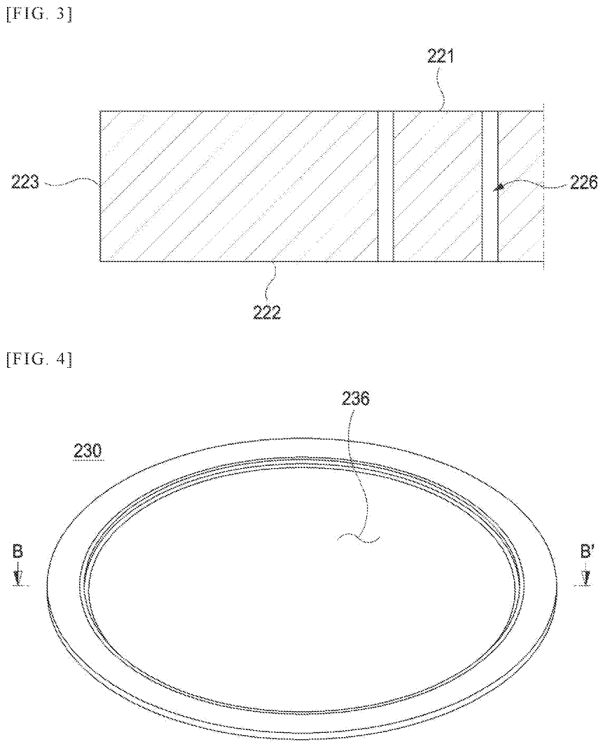

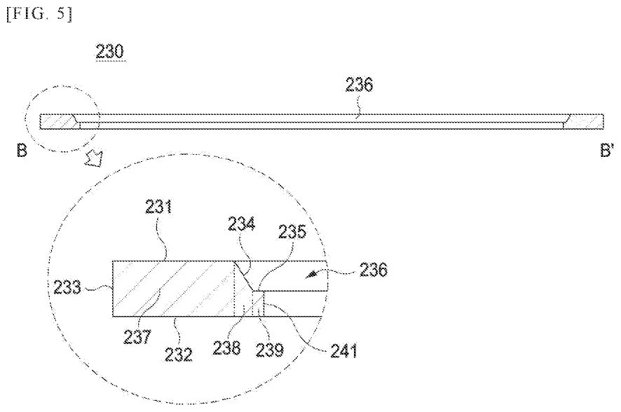

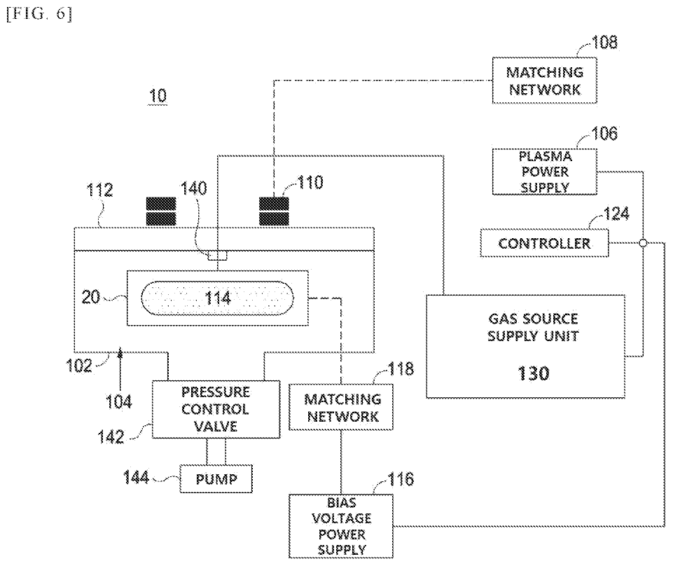

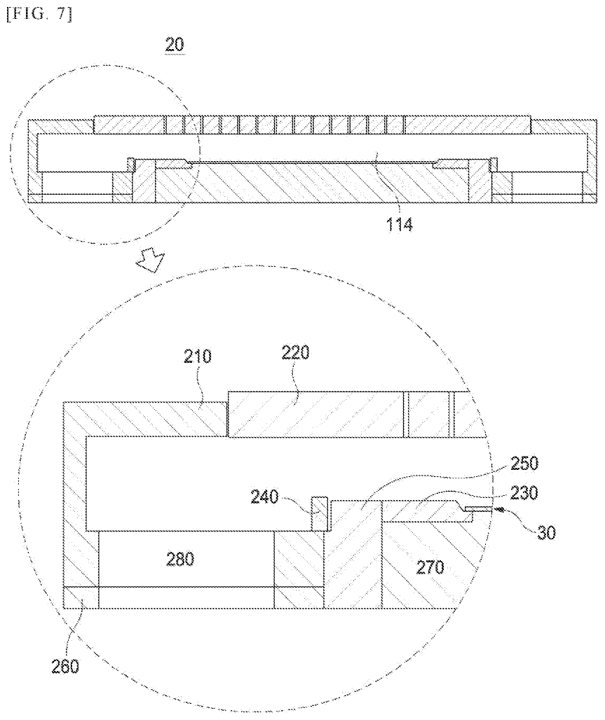

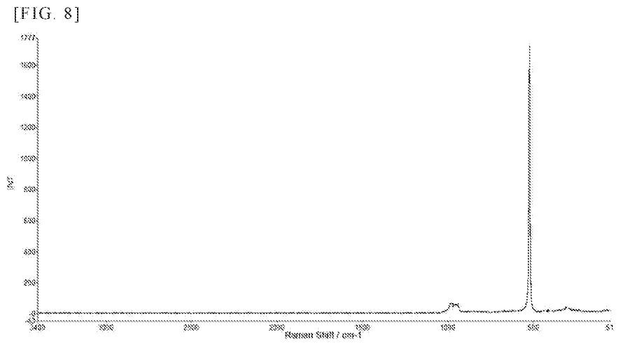

FIG. 1 illustrates an upper electrode according to an embodiment of the present disclosure. FIG. 2 is a cross-sectional view of an upper electrode according to an embodiment of the present disclosure. FIG. 3 is a cross-sectional view of an upper electrode according to another embodiment of the present disclosure. FIG. 4 is a perspective view of a focus ring according to an embodiment of the present disclosure. FIG. 5 is a cross-sectional view of a focus ring according to an embodiment of the present disclosure. FIG. 6 is a diagram for describing a semiconductor device fabrication apparatus according to an embodiment of the present disclosure. FIG. 7 is a cross-sectional view of a plasma region-confined assembly according to an embodiment of the present disclosure. FIG. 8 is the Raman spectrum of the upper surface of a focus ring according to Example 7.

Referring to FIGS. 1 to 3, an upper electrode 220 according to an embodiment may have an overall flat shape.

The upper electrode 220 may include a first upper surface 221, a first lower surface 222, and a first side 223.

The first upper surface 221 and the first lower surface 222 are formed to face each other.

The first upper surface 221 may be located in an area where a plasma forming gas flows. The first upper surface 221 may be flat overall.

The first lower surface 222 may be located in a plasma area 114. The first lower surface 222 may be flat overall. A portion of the first lower surface 222 may be sloped. A portion of the first lower surface 222 may form a stepped portion. A portion of the first lower surface 222 may be curved.

The first side 223 extends from the first upper surface 221 to the first lower surface 222. The first side 223 may be an outer circumferential surface of the upper electrode 220.

The upper electrode 220 may include a plurality of through-holes 226. The through-holes 226 extend from the first upper surface 221 to the first lower surface 222. A plasma forming gas may be sprayed to the first upper surface 221 and flow through the through-holes 226 to the bottom of the upper electrode 220.

The diameter of the through-holes 226 may be approximately 0.3 mm to approximately 1 mm.

A stepped portion may be formed on the first side 223. That is, a portion of the first side 223 and another portion of the first side 223 may be placed on different planes. Accordingly, the upper electrode 220 may include a stepped portion 225 on the first side 223.

The stepped portion 225 may be engaged with or coupled to other components of the semiconductor device fabrication apparatus.

As shown in FIG. 3, a stepped portion may not be formed on the first side 223, and the first side 223 may be flat overall. That is, in the first side 223, the stepped portion may be omitted.

Referring back to FIG. 2, the upper electrode 220 may include a first inclined surface 224. The first inclined surface 224 may extend laterally downward from the first lower surface 222. The first inclined surface 224 may guide plasma flowing from the through-holes 226. That is, the first inclined surface 224 guides plasma sprayed from the through-holes 226 to a semiconductor substrate 30 to be processed, thereby improving the efficiency of the semiconductor device fabrication process. In addition, since the first inclined surface 224 inhibits flow of plasma to other components, the upper electrode 220 may prevent other components from being eroded by the plasma.

In addition, as shown in FIG. 3, the first inclined surface may be omitted. That is, the first lower surface 222 may be formed to be entirely flat up to the first side 223.

In addition, the upper electrode 220 may further include a fastening groove formed for fastening with other components.

The upper electrode 220 may include single-crystal silicon. The upper electrode 220 may include the single-crystal silicon as a main component. The upper electrode 220 may include the single-crystal silicon in an amount of approximately 90 wt % or more. The upper electrode 220 may include the single-crystal silicon in an amount of approximately 95 wt % or more. The upper electrode 220 may include the single-crystal silicon in an amount of approximately 99 wt % or more. The upper electrode 220 may be substantially made of single-crystal silicon.

The upper electrode 220 may have an Si—OH ratio on at least one surface thereof.

The Si—OH ratio is a value obtained by dividing the area of an Si—OH peak by the area of an Si single-crystal peak. In addition, the Si—OH peak may be a peak at a Raman shift of 940 cm⁻¹ to 980 cm⁻¹ in the Raman spectrum of one surface of the component for a semiconductor device fabrication apparatus, such as the upper electrode 220 or a focus ring 230. The Si single-crystal peak may be a peak at a Raman shift of 520 cm⁻¹ to 522 cm⁻¹ in the Raman spectrum of one surface of the component for a semiconductor device fabrication apparatus, such as the upper electrode 220 or the focus ring 230.

The Si—OH ratio may be expressed as Equation 1 below.

Si—OH ratio=O/S [Equation 1]

In Equation 1, O is the area of an Si—OH peak, and S is the area of an Si single-crystal peak.

The Si—OH ratio on at least one surface of the upper electrode 220 may be approximately 0.16 to approximately 0.28. The Si—OH ratio on at least one surface of the upper electrode 220 may be approximately 0.17 to approximately 0.27. The Si—OH ratio on at least one surface of the upper electrode 220 may be approximately 0.18 to approximately 0.26. The Si—OH ratio on at least one surface of the upper electrode 220 may be approximately 0.19 to approximately 0.26.

Since the surface of the upper electrode 220 has the Si—OH ratio within the above-described range, even when process by-products are adsorbed, the process by-products may be easily desorbed and discharged. In addition, since the surface of the upper electrode 220 has the Si—OH ratio within the above-described range, even when a portion of the surface is ionized by plasma, generation of substances that cause defects may be suppressed.

One or more of the first upper surface 221, the first lower surface 222, the first side 223, and the first inclined surface 224 may have the Si—OH ratio within the above-described range.

Approximately 60% or more of the surface of the upper electrode 220 may have the Si—OH ratio within the above-described range. Approximately 70% or more of the surface of the upper electrode 220 may have the Si—OH ratio within the above-described range. Approximately 80% or more of the surface of the upper electrode 220 may have the Si—OH ratio within the above-described range. Approximately 90% or more of the surface of the upper electrode 220 may have the Si—OH ratio within the above-described range. Approximately 95% or more of the surface of the upper electrode 220 may have the Si—OH ratio within the above-described range.

Since the entire surface of the upper electrode 220 has the Si—OH ratio within the above-described range, the upper electrode 220 may reduce by-products generated during a plasma process.

Since the upper electrode 220 has the Si—OH ratio within the above-described range, the upper electrode 220 may have appropriate surface properties. Accordingly, contaminants may be prevented from remaining on the surface of the upper electrode 220.

In addition, since the upper electrode 220 has the Si—OH ratio within the above-described range, the upper electrode 220 may include a protective film on the surface thereof. Accordingly, the upper electrode 220 may be effectively protected from external contaminants.

The upper electrode 220 may have a dopant ratio on at least one surface thereof. The dopant ratio is a value obtained by dividing the area of a dopant peak by the area of an Si single-crystal peak. The dopant peak may be a peak at a Raman shift of approximately 303 cm⁻¹ to approximately 305 cm⁻¹ in the Raman spectrum of the surface of the upper electrode 220.

The dopant ratio on the surface of the upper electrode 220 may be calculated by Equation 2 below.

Dopant ratio=D/S [Equation 2]

In Equation 2, D represents the area of a dopant peak, and S represents the area of an Si single-crystal peak.

The dopant ratio on at least one surface of the upper electrode 220 may be less than approximately 0.12. The dopant ratio on at least one surface of the upper electrode 220 may be approximately 0.05 to approximately 0.12. The dopant ratio on at least one surface of the upper electrode 220 may be approximately 0.01 to approximately 0.12. The dopant ratio on at least one surface of the upper electrode 220 may be approximately 0.06 to approximately 0.13.

One or more of the first upper surface 221, the first lower surface 222, the first side 223, and the first inclined surface 224 may have a dopant ratio within the above-described range.

Approximately 60% or more of the surface of the upper electrode 220 may have a dopant ratio within the above-described range. Approximately 70% or more of the surface of the upper electrode 220 may have a dopant ratio within the above-described range. Approximately 80% or more of the surface of the upper electrode 220 may have a dopant ratio within the above-described range. Approximately 90% or more of the surface of the upper electrode 220 may have a dopant ratio within the above-described range. Approximately 95% or more of the surface of the upper electrode 220 may have a dopant ratio within the above-described range.

Since at least one surface of the upper electrode 220 has a dopant ratio within the above-described range, the upper electrode 220 may have appropriate surface conductivity. Accordingly, the upper electrode 220 may easily generate plasma. In addition, since at least one surface of the upper electrode 220 has a dopant ratio within the above-described range, erosion by plasma may be suppressed. Accordingly, the upper electrode 220 may have improved durability.

The upper electrode 220 may have a body-centered cubic ratio on at least one surface thereof. The body-centered cubic ratio is a value obtained by dividing the area of a body-centered cubic peak by the area of an Si single-crystal peak. The body-centered cubic peak may be a peak at a Raman shift of 433 cm⁻¹ to 435 cm⁻¹ in the Raman spectrum of the surface of the upper electrode 220.

The body-centered cubic ratio on the surface of the upper electrode 220 may be calculated by Equation 3 below.

Body-centered cubic ratio=C/S [Equation 3]

In Equation 3, C represents the area of a body-centered cubic peak, and S represents the area of an Si single-crystal peak.

The body-centered cubic ratio on at least one surface of the upper electrode 220 may be less than approximately 0.01. The body-centered cubic ratio on at least one surface of the upper electrode 220 may be less than approximately 0.005. The body-centered cubic ratio on at least one surface of the upper electrode 220 may be less than approximately 0.004. The body-centered cubic ratio on at least one surface of the upper electrode 220 may be less than approximately 0.001.

One or more of the first upper surface 221, the first lower surface 222, the first side 223, and the first inclined surface 224 may have a body-centered cubic ratio within the above-described range.

Approximately 60% or more of the surface of the upper electrode 220 may have a body-centered cubic ratio within the above-described range. Approximately 70% or more of the surface of the upper electrode 220 may have a body-centered cubic ratio within the above-described range. Approximately 80% or more of the surface of the upper electrode 220 may have a body-centered cubic ratio within the above-described range. Approximately 90% or more of the surface of the upper electrode 220 may have a body-centered cubic ratio within the above-described range. Approximately 95% or more of the surface of the upper electrode 220 may have a body-centered cubic ratio within the above-described range.

Since at least one surface of the upper electrode 220 has a body-centered cubic ratio within the above-described range, surface defect density may decrease. In particular, since at least one surface of the upper electrode 220 has a body-centered cubic ratio within the above-described range, the Si-III defect rate of a body-centered cubic structure may decrease.

Accordingly, the upper electrode 220 may suppress occurrence of defects on the surface thereof. In addition, since at least one surface of the upper electrode 220 has a body-centered cubic ratio within the above-described range, erosion by plasma may be suppressed. Accordingly, the upper electrode 220 may have improved durability.

The upper electrode 220 may have a rhombohedral ratio on at least one surface thereof. The dopant ratio is a value obtained by dividing the area of a rhombohedral peak by the area of an Si single-crystal peak. The rhombohedral peak may be a peak at a Raman shift of 348 cm⁻¹ to 350 cm⁻¹ in the Raman spectrum of the surface of the upper electrode 220.

The rhombohedral ratio on the surface of the upper electrode 220 may be calculated by Equation 4 below.

Rhombohedral ratio=C/S [Equation 4]

In Equation 4, C represents the area of a rhombohedral peak, and S represents the area of an Si single-crystal peak.

The rhombohedral ratio on at least one surface of the upper electrode 220 may be less than approximately 0.01. The rhombohedral ratio on at least one surface of the upper electrode 220 may be less than approximately 0.005. The rhombohedral ratio on at least one surface of the upper electrode 220 may be less than approximately 0.004. The rhombohedral ratio on at least one surface of the upper electrode 220 may be less than approximately 0.001.

One or more of the first upper surface 221, the first lower surface 222, the first side 223, and the first inclined surface 224 may have a rhombohedral ratio within the above-described range.

Approximately 60% or more of the surface of the upper electrode 220 may have a rhombohedral ratio within the above-described range. Approximately 70% or more of the surface of the upper electrode 220 may have a rhombohedral ratio within the above-described range. Approximately 80% or more of the surface of the upper electrode 220 may have a rhombohedral ratio within the above-described range. Approximately 90% or more of the surface of the upper electrode 220 may have a rhombohedral ratio within the above-described range. Approximately 95% or more of the surface of the upper electrode 220 may have a rhombohedral ratio within the above-described range.

Since at least one surface of the upper electrode 220 has a rhombohedral ratio within the above-described range, surface defect density may decrease. In particular, since at least one surface of the upper electrode 220 has a rhombohedral ratio within the above-described range, the ratio of Si-XII defects in a rhombohedral structure may be reduced.

Among the surfaces of the upper electrode 220, more than approximately 90% may have an Si—OH ratio, a dopant ratio, a body-centered cubic ratio, or a rhombohedral ratio within the above-described ranges.

Accordingly, the upper electrode 220 may suppress occurrence of defects on the substrate. In addition, since at least one surface of the upper electrode 220 has a rhombohedral ratio within the above-described range, erosion by plasma may be suppressed. Accordingly, the upper electrode 220 may have improved durability.

The Raman spectrum may be measured using a Raman spectroscope using an argon laser source. In this case, the wavelength of the laser source may be approximately 514.5 nm. The areas of the Si single-crystal peak, the Si—OH peak, the dopant peak, the body-centered cubic peak, and the rhombohedral peak may be calculated automatically by a program within a Raman spectroscope. The areas of the peaks may be measured and calculated by a micro Raman spectroscope (Jobin Yvon Spex T64000), TPIR-785 manufactured by Princeton Instruments, Monowave 400R manufactured by Anton Paar, FT-Raman spectroscope: multi-RAM manufactured by Bruker, or uRaman-M manufactured by Technospex.

The areas of the peaks may be calculated manually. For example, the baselines of the peaks are defined, and the area for each peak and the area within the baseline for each peak may be calculated based on the areas of the peaks. For example, the baseline of the Si—OH peak may be a straight line from a Raman spectrum intensity of 903 cm⁻¹ to a Raman spectrum intensity of 1056 cm⁻¹. The baseline of the Si single-crystal peak may be a straight line from a Raman spectrum intensity of 468 cm⁻¹ to a Raman spectrum intensity of 556 cm⁻¹. The baseline of the dopant peak may be a straight line from a Raman spectrum intensity of 274 cm⁻¹ to a Raman spectrum intensity of 339 cm⁻¹. The baseline of the body-centered cubic peak may be a straight line from a Raman spectrum intensity of 423 cm⁻¹ to a Raman spectrum intensity of 445 cm⁻¹. The baseline of the rhombohedral peak may be a straight line from a Raman spectrum intensity of 338 cm⁻¹ to a Raman spectrum intensity of 360 cm⁻¹.

The first upper surface 221 may have Sk roughness. The Sk roughness of the first upper surface 221 may be approximately 0.005 μm to approximately 3 μm. The Sk roughness of the first upper surface 221 may be approximately 0.005 μm to approximately 1 μm. The Sk roughness of the first upper surface 221 may be approximately 0.01 μm to approximately 0.5 μm. The Sk roughness of the first upper surface 221 may be approximately 1 μm to approximately 2 μm. The Sk roughness of the first upper surface 221 may be approximately 1 μm to approximately 1.5 μm.

The first lower surface 222 may have Sk roughness. The Sk roughness of the first lower surface 222 may be approximately 0.005 μm to approximately 3 μm. The Sk roughness of the first lower surface 222 may be approximately 0.005 μm to approximately 1 μm. The Sk roughness of the first lower surface 222 may be approximately 0.01 μm to approximately 0.5 μm. The Sk roughness of the first lower surface 222 may be approximately 1 μm to approximately 2 μm. The Sk roughness of the first lower surface 222 may be approximately 1 μm to approximately 1.5 μm.

The first side 223 may have Sk roughness. The Sk roughness of the first side 223 may be greater than the Sk roughness of the first upper surface 221. The Sk roughness of the first side 223 may be greater than the Sk roughness of the first lower surface 222. The Sk roughness of the first side 223 may be approximately 0.005 μm to approximately 1 μm. The Sk roughness of the first side 223 may be approximately 0.01 μm to approximately 0.5 μm. The Sk roughness of the first side 223 may be approximately 1 μm to approximately 2 μm. The Sk roughness of the first side 223 may be approximately 1 μm to approximately 1.5 μm.

The first inclined surface 224 may have Sk roughness. The Sk roughness of the first inclined surface 224 may be greater than the Sk roughness of the first upper surface 221. The Sk roughness of the first inclined surface 224 may be greater than the Sk roughness of the first lower surface 222. The Sk roughness of the first inclined surface 224 may be approximately 0.005 μm to approximately 1 μm. The Sk roughness of the first inclined surface 224 may be approximately 0.01 μm to approximately 0.5 μm. The Sk roughness of the first inclined surface 224 may be approximately 1 μm to approximately 2 μm. The Sk roughness of the first inclined surface 224 may be approximately 1 μm to approximately 1.5 μm.

Since the first upper surface 221, the first lower surface 222, the first side 223, or the first inclined surface 224 has Sk roughness within the above-described range, a microfluidic channel through which plasma flows freely may be included. Accordingly, in the first upper surface 221, the first lower surface 222, the first side 223, or the first inclined surface 224, plasma may flow properly.

The first upper surface 221 may have Spk roughness. The Spk roughness of the first upper surface 221 may be approximately 0.001 μm to approximately 1 μm. The Spk roughness of the first upper surface 221 may be approximately 0.001 μm to approximately 0.7 μm. The Spk roughness of the first upper surface 221 may be approximately 0.003 μm to approximately 0.7 μm. The Spk roughness of the first upper surface 221 may be approximately 0.1 μm to approximately 1 μm. The Spk roughness of the first upper surface 221 may be approximately 0.001 μm to approximately 0.1 μm.

The first lower surface 222 may have Spk roughness. The Spk roughness of the first lower surface 222 may be approximately 0.001 μm to approximately 0.7 μm. The Spk roughness of the first lower surface 222 may be approximately 0.003 μm to approximately 0.7 μm. The Spk roughness of the first lower surface 222 may be approximately 0.1 μm to approximately 1 μm. The Spk roughness of the first lower surface 222 may be approximately 0.001 μm to approximately 0.1 μm.

The first side 223 may have Spk roughness. The Spk roughness of the first side 223 may be greater than the Spk roughness of the first upper surface 221. The Spk roughness of the first side 223 may be greater than the Spk roughness of the first lower surface 222. The Spk roughness of the first side 223 may be approximately 0.1 μm to approximately 1 μm. The Spk roughness of the first side 223 may be approximately 0.08 μm to approximately 0.7 μm. The Spk roughness of the first side 223 may be approximately 0.2 μm to approximately 1 μm. The Spk roughness of the first side 223 may be approximately 0.2 μm to approximately 0.7 μm.

The first inclined surface 224 may have Spk roughness. The Spk roughness of the first inclined surface 224 may be greater than the Spk roughness of the first upper surface 221. The Spk roughness of the first inclined surface 224 may be greater than the Spk roughness of the first lower surface 222. The Spk roughness of the first side 223 may be greater than the Spk roughness of the first lower surface 222. The Spk roughness of the first side 223 may be approximately 0.1 μm to approximately 1 μm. The Spk roughness of the first side 223 may be approximately 0.08 μm to approximately 0.7 μm. The Spk roughness of the first side 223 may be approximately 0.2 μm to approximately 1 μm. The Spk roughness of the first side 223 may be approximately 0.2 μm to approximately 0.7 μm. The Spk roughness of the first inclined surface 224 may be approximately 0.002 μm to approximately 0.2 μm.

The Spk roughness may be one of important parameters that provide an initial contact area when plasma contacts a surface during a surface etching process. In addition, the Spk roughness may indicate the height of a micro-mountain that may be removed during the plasma process.

Since the first upper surface 221, the first lower surface 222, the first side 223, or the first inclined surface 224 has Spk roughness within the above-described range, generation of impurities and process by-products due to micro-mountain etching may be reduced.

The first upper surface 221 may have Svk roughness. The Svk roughness of the first upper surface 221 may be approximately 0.002 μm to approximately 2 μm. The Svk roughness of the first upper surface 221 may be approximately 0.002 μm to approximately 1.7 μm. The Svk roughness of the first upper surface 221 may be approximately 0.004 μm to approximately 1.5 μm. The Svk roughness of the first upper surface 221 may be approximately 0.1 μm to approximately 1.5 μm. The Svk roughness of the first upper surface 221 may be approximately 0.001 μm to approximately 0.2 μm.

The first lower surface 222 may have Svk roughness. The Svk roughness of the first lower surface 222 may be approximately 0.001 μm to approximately 0.7 μm. The Svk roughness of the first lower surface 222 may be approximately 0.002 μm to approximately 1.7 μm. The Svk roughness of the first lower surface 222 may be approximately 0.004 μm to approximately 1.5 μm. The Svk roughness of the first lower surface 222 may be approximately 0.1 μm to approximately 1.5 μm. The Svk roughness of the first lower surface 222 may be approximately 0.001 μm to approximately 0.2 μm.

The first side 223 may have Svk roughness. The Svk roughness of the first side 223 may be greater than the Svk roughness of the first upper surface 221. The Svk roughness of the first side 223 may be greater than the Svk roughness of the first lower surface 222. The Svk roughness of the first side 223 may be approximately 0.15 μm to approximately 1.5 μm. The Svk roughness of the first side 223 may be approximately 0.2 μm to approximately 1.7 μm. The Svk roughness of the first side 223 may be approximately 0.5 μm to approximately 1.8 μm. The Svk roughness of the first side 223 may be approximately 0.4 μm to approximately 1.5 μm.

The first inclined surface 224 may have Svk roughness. The Svk roughness of the first inclined surface 224 may be greater than the Svk roughness of the first upper surface 221. The Svk roughness of the first inclined surface 224 may be greater than the Svk roughness of the first lower surface 222. The Svk roughness of the first inclined surface 224 may be approximately 0.15 μm to approximately 1.5 μm. The Svk roughness of the first inclined surface 224 may be approximately 0.2 μm to approximately 1.7 μm. The Svk roughness of the first inclined surface 224 may be approximately 0.5 μm to approximately 1.8 μm. The Svk roughness of the first inclined surface 224 may be approximately 0.4 μm to approximately 1.5 μm.

Since the first upper surface 221, the first lower surface 222, the first side 223, or the first inclined surface 224 has Svk roughness within the above-described range, deposition of process by-products in micro-valleys on the surface may be prevented.

The first upper surface 221 may have Sv roughness. The Sv roughness of the first upper surface 221 may be approximately −3 μm to approximately −0.01 μm. The Sv roughness of the first upper surface 221 may be approximately −2.5 μm to approximately −0.01 μm. The Sv roughness of the first upper surface 221 may be approximately −0.1 μm to approximately −0.01 μm. The Sv roughness of the first upper surface 221 may be approximately −2.5 μm to approximately −1 μm. The Sv roughness of the first upper surface 221 may be approximately −3 μm to approximately −0.7 μm.

The first lower surface 222 may have Sv roughness. The Sv roughness of the first lower surface 222 may be approximately −3 μm to approximately −0.01 μm. The Sv roughness of the first lower surface 222 may be approximately −2.5 μm to approximately −0.01 μm. The Sv roughness of the first lower surface 222 may be approximately −0.1 μm to approximately −0.01 μm. The Sv roughness of the first lower surface 222 may be approximately −2.5 μm to approximately −1 μm. The Sv roughness of the first lower surface 222 may be approximately −3 μm to approximately −0.7 μm.

The first side 223 may have Sv roughness. The Sv roughness of the first side 223 may be lower than the Sv roughness of the first upper surface 221. The Sv roughness of the first side 223 may be lower than the Sv roughness of the first lower surface 222. The Sv roughness of the first side 223 may be approximately −3 μm to approximately −0.1 μm. The Sv roughness of the first side 223 may be approximately −2.5 μm to approximately −0.3 μm. The Sv roughness of the first side 223 may be approximately −2.5 μm to approximately −0.5 μm. The Sv roughness of the first side 223 may be approximately −2.5 μm to approximately −1 μm. The Sv roughness of the first side 223 may be approximately −3 μm to approximately −0.7 μm.

The first inclined surface 224 may have Sv roughness. The Sv roughness of the first inclined surface 224 may be lower than the Sv roughness of the first upper surface 221. The Sv roughness of the first inclined surface 224 may be lower than the Sv roughness of the first lower surface 222. The Sv roughness of the first inclined surface 224 may be approximately −3 μm to approximately −0.1 μm. The Sv roughness of the first inclined surface 224 may be approximately −2.5 μm to approximately −0.3 μm. The Sv roughness of the first inclined surface 224 may be approximately −2.5 μm to approximately −0.5 μm. The Sv roughness of the first inclined surface 224 may be approximately −2.5 μm to approximately −1 μm. The Sv roughness of the first inclined surface 224 may be approximately −3 μm to approximately −0.7 μm.

The first upper surface 221 may have Sz roughness. The Sz roughness of the first upper surface 221 may be approximately 0.01 μm to approximately 6 μm. The Sz roughness of the first upper surface 221 may be approximately 0.02 μm to approximately 1 μm. The Sz roughness of the first upper surface 221 may be approximately 1.5 μm to approximately 6 μm. The Sz roughness of the first upper surface 221 may be approximately 1.5 μm to approximately 5 μm. The Sz roughness of the first upper surface 221 may be approximately 0.03 μm to approximately 0.7 μm.

The first lower surface 222 may have Sz roughness. The Sz roughness of the first lower surface 222 may be approximately 0.01 μm to approximately 6 μm. The Sz roughness of the first lower surface 222 may be approximately 0.02 μm to approximately 1 μm. The Sz roughness of the first lower surface 222 may be approximately 1.5 μm to approximately 6 μm. The Sz roughness of the first lower surface 222 may be approximately 1.5 μm to approximately 5 μm. The Sz roughness of the first lower surface 222 may be approximately 0.03 μm to approximately 0.7 μm.

The first side 223 may have Sz roughness. The Sz roughness of the first side 223 may be greater than the Sz roughness of the first upper surface 221. The Sz roughness of the first side 223 may be greater than the Sz roughness of the first lower surface 222. The Sz roughness of the first side 223 may be approximately 1.5 μm to approximately 6 μm. The Sz roughness of the first side 223 may be approximately 1.5 μm to approximately 5 μm. The Sz roughness of the first side 223 may be approximately 0.03 μm to approximately 0.7 μm.

The first inclined surface 224 may have Sz roughness. The Sz roughness of the first inclined surface 224 may be greater than the Sz roughness of the first upper surface 221. The Sz roughness of the first inclined surface 224 may be greater than the Sz roughness of the first lower surface 222. The Sz roughness of the first inclined surface 224 may be approximately 1.5 μm to approximately 6 μm. The Sz roughness of the first inclined surface 224 may be approximately 1.5 μm to approximately 5 μm. The Sz roughness of the first inclined surface 224 may be approximately 0.03 μm to approximately 0.7 μm.

Since the first upper surface 221, the first lower surface 222, the first side 223, and the first inclined surface 224 have Sz roughness within the above-described range, plasma flowability may be improved. Accordingly, since the first upper surface 221, the first lower surface 222, the first side 223, and the first inclined surface 224 have Sz roughness within the above-described range, deposition of process by-products on the surfaces may be prevented. Accordingly, the upper electrode 220 may have less defects.

The first upper surface 221 may have Sp roughness. The Sp roughness of the first upper surface 221 may be approximately 0.01 μm to approximately 4 μm. The Sp roughness of the first upper surface 221 may be approximately 0.02 μm to approximately 3.5 μm. The Sp roughness of the first upper surface 221 may be approximately 0.8 μm to approximately 3 μm. The Sp roughness of the first upper surface 221 may be approximately 1 μm to approximately 3 μm. The Sp roughness of the first upper surface 221 may be approximately 0.01 μm to approximately 0.7 μm.

The first lower surface 222 may have Sp roughness. The Sp roughness of the first lower surface 222 may be approximately 0.01 μm to approximately 4 μm. The Sp roughness of the first lower surface 222 may be approximately 0.02 μm to approximately 3.5 μm. The Sp roughness of the first lower surface 222 may be approximately 0.8 μm to approximately 3 μm. The Sp roughness of the first lower surface 222 may be approximately 1 μm to approximately 3 μm. The Sp roughness of the first lower surface 222 may be approximately 0.01 μm to approximately 0.7 μm.

The first side 223 may have Sp roughness. The Sp roughness of the first side 223 may be greater than the Sp roughness of the first upper surface 221. The Sp roughness of the first side 223 may be greater than the Sp roughness of the first lower surface 222. The Sp roughness of the first side 223 may be approximately 0.02 μm to approximately 3.5 μm. The Sp roughness of the first side 223 may be approximately 0.8 μm to approximately 3 μm. The Sp roughness of the first side 223 may be approximately 1 μm to approximately 3 μm. The Sp roughness of the first side 223 may be approximately 1 μm to approximately 4 μm.

The first inclined surface 224 may have Sp roughness. The Sp roughness of the first inclined surface 224 may be greater than the Sp roughness of the first upper surface 221. The Sp roughness of the first inclined surface 224 may be greater than the Sp roughness of the first lower surface 222. The Sp roughness of the first inclined surface 224 may be approximately 0.02 μm to approximately 3.5 μm. The Sp roughness of the first inclined surface 224 may be approximately 0.8 μm to approximately 3 μm. The Sp roughness of the first inclined surface 224 may be approximately 1 μm to approximately 3 μm. The Sp roughness of the first inclined surface 224 may be approximately 1 μm to approximately 4 μm.

The Sk roughness, the Spk roughness, the Svk roughness, the Sv roughness, the Sz roughness, and the Sp roughness may be measured using a non-contact 3D roughness measuring device. The Sk roughness, the Spk roughness, the Svk roughness, the Sv roughness, the Sz roughness, and the Sp roughness may be calculated by ISO 25178-2. The Sk roughness, the Spk roughness, the Svk roughness, the Sv roughness, the Sz roughness, and the Sp roughness may be measured at 5 to 10 points and may be obtained as an average value of the measurement values excluding the minimum and maximum measurement values.

In addition, the Sk roughness, the Spk roughness, and the Svk roughness may be calculated based on the bearing area curve of the surface of the upper electrode 220 obtained using a 3D roughness measuring device. The bearing area curve may be a graph obtained by plotting accumulated data according to height measured for a unit area using a surface roughness measuring device. At this time, the Sk roughness may mean the width of height at a core surface in the accumulated data plot. In addition, the Spk roughness may mean the average height of peaks above the core surface, and the Svk roughness may mean the average depth of valleys below the core surface.

At least one surface of the upper electrode 220 may have a reduced peak valley (Spvk) roughness. The Spvk roughness is the sum of the Spk roughness and the Svk roughness. The reduced peak valley roughness may be represented by Equation 5 below.

Spvk roughness=Spk roughness+Svk roughness [Equation 5]

The first upper surface 221 may have Spvk roughness. The Spvk roughness of the first upper surface 221 may be approximately 0.005 μm to approximately 2 μm. The Spvk roughness of the first upper surface 221 may be approximately 0.007 μm to approximately 2 μm. The Spvk roughness of the first upper surface 221 may be approximately 0.005 μm to approximately 0.1 μm. The Spvk roughness of the first upper surface 221 may be approximately 0.5 μm to approximately 2 μm. The Spvk roughness of the first upper surface 221 may be approximately 0.7 μm to approximately 1.7 μm.

The first lower surface 222 may have Spvk roughness. The Spvk roughness of the first lower surface 222 may be approximately 0.005 μm to approximately 2 μm. The Spvk roughness of the first lower surface 222 may be approximately 0.007 μm to approximately 2 μm. The Spvk roughness of the first lower surface 222 may be approximately 0.005 μm to approximately 0.1 μm. The Spvk roughness of the first lower surface 222 may be approximately 0.5 μm to approximately 2 μm. The Spvk roughness of the first lower surface 222 may be approximately 0.7 μm to approximately 1.7 μm.

The first side 223 may have Spvk roughness. The Spvk roughness of the first side 223 may be greater than the Spvk roughness of the first upper surface 221. The Spvk roughness of the first side 223 may be greater than the Spvk roughness of the first lower surface 222. The Spvk roughness of the first side 223 may be approximately 0.5 μm to approximately 2 μm. The Spvk roughness of the first side 223 may be approximately 0.7 μm to approximately 1.7 μm.

The first inclined surface 224 may have Spvk roughness. The Spvk roughness of the first inclined surface 224 may be greater than the Spvk roughness of the first upper surface 221. The Spvk roughness of the first inclined surface 224 may be greater than the Spvk roughness of the first lower surface 222. The Spvk roughness of the first inclined surface 224 may be approximately 0.007 μm to approximately 2 μm. The Spvk roughness of the first inclined surface 224 may be approximately 0.005 μm to approximately 0.1 μm. The Spvk roughness of the first inclined surface 224 may be approximately 0.5 μm to approximately 2 μm. The Spvk roughness of the first inclined surface 224 may be approximately 0.7 μm to approximately 1.7 μm.

The Spvk roughness may be roughness regarding the shapes and sizes of micro-irregularities (micro-mountains and micro-valleys). Since the first upper surface 221, the first lower surface 222, the first side 223, or the first inclined surface 224 has Spvk roughness within the above-described range, micro-irregularities on the surface may have appropriate shapes and sizes. Accordingly, since the first upper surface 221, the first lower surface 222, the first side 223, or the first inclined surface 224 has Spvk roughness within the above-described range, deposition of process by-products in micro-irregularities on the surface or generation of debris causing defects on the surface may be prevented. In addition, since the first upper surface 221, the first lower surface 222, the first side 223, or the first inclined surface 224 has Spvk roughness within the above-described range, plasma flowability on the surface may be improved.

At least one surface of the upper electrode 220 may have a reduced peak valley ratio (Rpvk).

The reduced peak valley ratio is a value obtained by dividing the reduced peak valley roughness by the Sk roughness. The reduced peak valley ratio may be represented by Equation 6 below.

Rpvk=Spvk roughness/Sk roughness [Equation 6]

The first upper surface 221 may have Rpvk. The Rpvk of the first upper surface 221 may be approximately 0.5 to approximately 4. The Rpvk of the first upper surface 221 may be approximately 0.5 to approximately 1.3. The Rpvk of the first upper surface 221 may be approximately 0.5 to approximately 1. The Rpvk of the first upper surface 221 may be approximately 0.6 to approximately 1.2. The Rpvk of the first upper surface 221 may be approximately 0.5 to approximately 1.1.

The first lower surface 222 may have Rpvk. The Rpvk of the first lower surface 222 may be approximately 0.5 to approximately 4. The Rpvk of the first lower surface 222 may be approximately 0.5 to approximately 1.3. The Rpvk of the first lower surface 222 may be approximately 0.5 to approximately 1. The Rpvk of the first lower surface 222 may be approximately 0.6 to approximately 1.2. The Rpvk of the first lower surface 222 may be approximately 0.5 to approximately 1.1.

The first side 223 may have Rpvk. The Rpvk of the first side 223 may be approximately 0.5 to approximately 4. The Rpvk of the first side 223 may be approximately 0.5 to approximately 1.3. The Rpvk of the first side 223 may be approximately 0.5 to approximately 1. The Rpvk of the first side 223 may be approximately 0.6 to approximately 1.2. The Rpvk of the first side 223 may be approximately 0.5 to approximately 1.1.

The first inclined surface 224 may have Rpvk. The Rpvk of the first inclined surface 224 may be approximately 0.5 to approximately 4. The Rpvk of the first inclined surface 224 may be approximately 0.5 to approximately 1.3. The Rpvk of the first inclined surface 224 may be approximately 0.5 to approximately 1. The Rpvk of the first inclined surface 224 may be approximately 0.6 to approximately 1.2. The Rpvk of the first inclined surface 224 may be approximately 0.5 to approximately 1.1.

The Rpvk may be the ratio of micro-mountains and micro-valleys at the middle portion of micro-irregularities. Since the first upper surface 221, the first lower surface 222, the first inclined surface 224, or the second inclined surface 234 has Rpvk in the above-described range, the micro-irregularities in the surface may have appropriate shapes. Accordingly, since the first upper surface 221, the first lower surface 222, the first inclined surface 224, or the second inclined surface 234 has Rpvk in the above-described range, deposition of process by-products in micro-irregularities on the surface or generation of debris causing defects on the surface may be prevented. In addition, since the first upper surface 221, the first lower surface 222, the first inclined surface 224, or the second inclined surface 234 has Rpvk in the above-described range, plasma flowability on the surface may be improved.

At least one surface of the upper electrode 220 may have total peak valley (Spv) roughness. The total peak valley roughness is the sum of the absolute value of the Sp roughness and the absolute value of the Sv roughness. The total peak valley roughness may be represented by Equation 7 below.

Spv roughness=|Sp roughness|+|Sv roughness| [Equation 7]

The first upper surface 221 may have Spy roughness. The Spy roughness of the first upper surface 221 may be approximately 0.01 μm to approximately 6 μm. The Spy roughness of the first upper surface 221 may be approximately 0.02 μm to approximately 5.5 μm. The Spy roughness of the first upper surface 221 may be approximately 0.01 μm to approximately 1 μm. The Spy roughness of the first upper surface 221 may be approximately 1 μm to approximately 6 μm. The Spy roughness of the first upper surface 221 may be approximately 1.5 μm to approximately 5 μm.

The first lower surface 222 may have Spy roughness. The Spy roughness of the first lower surface 222 may be approximately 0.01 μm to approximately 6 μm. The Spy roughness of the first lower surface 222 may be approximately 0.02 μm to approximately 5.5 μm. The Spy roughness of the first lower surface 222 may be approximately 0.01 μm to approximately 1 μm. The Spy roughness of the first lower surface 222 may be approximately 1 μm to approximately 6 μm. The Spy roughness of the first lower surface 222 may be approximately 1.5 μm to approximately 5 μm.

The first side 223 may have Spy roughness. The Spy roughness of the first side 223 may be greater than the Spy roughness of the first upper surface 221. The Spy roughness of the first side 223 may be greater than The Spy roughness of the first lower surface 222. The Spy roughness of the first side 223 may be approximately 0.02 μm to approximately 5.5 μm. The Spy roughness of the first side 223 may be approximately 1 μm to approximately 6 μm. The Spy roughness of the first side 223 may be approximately 1.5 μm to approximately 5 μm.

The first inclined surface 224 may have Spy roughness. The Spy roughness of the first inclined surface 224 may be greater than the Spy roughness of the first upper surface 221. The Spy roughness of the first inclined surface 224 may be greater than the Spy roughness of the first lower surface 222. The Spy roughness of the first inclined surface 224 may be approximately 0.007 μm to approximately 2 μm. The Spy roughness of the first inclined surface 224 may be approximately 0.02 μm to approximately 5.5 μm. The Spy roughness of the first inclined surface 224 may be approximately 1 μm to approximately 6 μm. The Spy roughness of the first inclined surface 224 may be approximately 1.5 μm to approximately 5 μm.

The Spy roughness may be roughness representing the overall size of micro-irregularities from a micro-mountain to a micro-valley. Since the first upper surface 221, the first lower surface 222, the first side 223, or the first inclined surface 224 has Spy roughness within the above-described range, the micro-irregularities in the surface may have appropriate sizes. Accordingly, since the first upper surface 221, the first lower surface 222, the first side 223, or the first inclined surface 224 has Spy roughness within the above-described range, deposition of process by-products in micro-irregularities on the surface or generation of debris causing defects on the surface may be prevented. In addition, since the first upper surface 221, the first lower surface 222, the first side 223, or the first inclined surface 224 has Spy roughness within the above-described range, plasma flowability on the surface may be improved.

More than approximately 90% of each side of the upper electrode 220 may have the Sk roughness, the Spk roughness, the Svk roughness, the Sv roughness, the Sz roughness, the Sp roughness, the Spvk roughness, the Spy roughness, and/or the Rpvk within the above-described ranges.

Since the upper electrode 220 has the Sk roughness, the Spk roughness, the Svk roughness, the Sv roughness, the Sz roughness, the Sp roughness, the Spvk roughness, the Spy roughness, and/or the Rpvk within the above-described ranges, plasma may be generated and controlled effectively.

In addition, since the upper electrode 220 has the Sk roughness, the Spk roughness, the Svk roughness, the Sv roughness, the Sz roughness, the Sp roughness, the Spvk roughness, the Spy roughness, and/or the Rpvk within the above-described ranges, generation of particles that cause defects may be prevented.

In addition, since the upper electrode 220 has the Sk roughness, the Spk roughness, the Svk roughness, the Sv roughness, the Sz roughness, the Sp roughness, the Spvk roughness, the Spy roughness, and/or the Rpvk within the above-described ranges, erosion may be suppressed and durability may be improved.

At least one surface of the upper electrode 220 may have a first contact angle with respect to water.

The first contact angle at the first upper surface 221 may be approximately 45° to approximately 74°. The first contact angle at the first upper surface 221 may be approximately 47° to approximately 73°. The first contact angle at the first upper surface 221 may be approximately 60° to approximately 74°. The first contact angle at the first upper surface 221 may be approximately 45° to approximately 60°.

The first contact angle at the first lower surface 222 may be approximately 45° to approximately 74°. The first contact angle at the first lower surface 222 may be approximately 47° to approximately 73°. The first contact angle at the first lower surface 222 may be approximately 60° to approximately 74°. The first contact angle at the first lower surface 222 may be approximately 45° to approximately 60°.

The first contact angle at the first side 223 may be less than the first contact angle at the first upper surface 221. The first contact angle at the first side 223 may be less than the first contact angle at the first lower surface 222. The first contact angle at the first side 223 may be approximately 45° to approximately 73°. The first contact angle at the first side 223 may be approximately 45° to approximately 70°. The first contact angle at the first side 223 may be approximately 550 to approximately 65°. The first contact angle at the first side 223 may be approximately 45° to approximately 60°.

The first contact angle at the first inclined surface 224 may be less than the first contact angle at the first upper surface 221. The first contact angle at the first inclined surface 224 may be less than the first contact angle at the first lower surface 222. The first contact angle at the first inclined surface 224 may be approximately 45° to approximately 73°. The first contact angle at the first inclined surface 224 may be approximately 45° to approximately 70°. The first contact angle at the first inclined surface 224 may be approximately 55° to approximately 65°. The first contact angle at the first inclined surface 224 may be approximately 45° to approximately 60°.

At least one surface of the upper electrode 220 may have a second contact angle with respect to diiodomethane.

The second contact angle at the first upper surface 221 may be approximately 41° to approximately 57°. The second contact angle at the first upper surface 221 may be approximately 42° to approximately 55°. The second contact angle at the first upper surface 221 may be approximately 45° to approximately 55°. The second contact angle at the first upper surface 221 may be approximately 40° to approximately 50°.

The second contact angle at the first lower surface 222 may be approximately 41° to approximately 57°. The second contact angle at the first lower surface 222 may be approximately 42° to approximately 55°. The second contact angle at the first lower surface 222 may be approximately 45° to approximately 55°. The second contact angle at the first lower surface 222 may be approximately 40° to approximately 50°.

The second contact angle at the first side 223 may be approximately 41° to approximately 57°. The second contact angle at the first side 223 may be approximately 42° to approximately 55°. The second contact angle at the first side 223 may be approximately 45° to approximately 55°. The second contact angle at the first side 223 may be approximately 40° to approximately 50°.

The second contact angle at the first inclined surface 224 may be approximately 41° to approximately 57°. The second contact angle at the first inclined surface 224 may be approximately 42° to approximately 55°. The second contact angle at the first inclined surface 224 may be approximately 45° to approximately 55°. The second contact angle at the first inclined surface 224 may be approximately 40° to approximately 50°.

At least one surface of the upper electrode 220 may have surface free energy.

The surface free energy of the first upper surface 221 may be approximately 40 mN/m to approximately 65 mN/m. The surface free energy of the first upper surface 221 may be approximately 35 mN/m to approximately 65 mN/m. The surface free energy of the first upper surface 221 may be approximately 40 mN/m to approximately 55 mN/m. The surface free energy of the first upper surface 221 may be approximately 50 mN/m to approximately 65 mN/m.

The surface free energy of the first lower surface 222 may be approximately 40 mN/m to approximately 65 mN/m. The surface free energy of the first lower surface 222 may be approximately 35 mN/m to approximately 65 mN/m. The surface free energy of the first lower surface 222 may be approximately 40 mN/m to approximately 55 mN/m. The surface free energy of the first lower surface 222 may be approximately 50 mN/m to approximately 65 mN/m.

The surface free energy of the first side 223 may be greater than the surface free energy of the first upper surface 221. The surface free energy of the first side 223 may be greater than the surface free energy of the first lower surface 222. The surface free energy of the first side 223 may be approximately 42 mN/m to approximately 65 mN/m. The surface free energy of the first side 223 may be approximately 40 mN/m to approximately 65 mN/m. The surface free energy of the first side 223 may be approximately 47 mN/m to approximately 65 mN/m. The surface free energy of the first side 223 may be approximately 50 mN/m to approximately 65 mN/m.

The surface free energy of the first inclined surface 224 may be greater than the surface free energy of the first upper surface 221. The surface free energy of the first inclined surface 224 may be greater than the surface free energy of the first lower surface 222. The surface free energy of the first inclined surface 224 may be approximately 42 mN/m to approximately 65 mN/m. The surface free energy of the first inclined surface 224 may be approximately 47 mN/m to approximately 65 mN/m. The surface free energy of the first inclined surface 224 may be approximately 50 mN/m to approximately 65 mN/m. The surface free energy of the first inclined surface 224 may be approximately 40 mN/m to approximately 65 mN/m.

At least one surface of the upper electrode 220 may have dispersion free energy.

The dispersion free energy of the first upper surface 221 may be approximately 30 mN/m to approximately 45 mN/m. The dispersion free energy of the first upper surface 221 may be approximately 30 mN/m to approximately 40 mN/m. The dispersion free energy of the first upper surface 221 may be approximately 25 mN/m to approximately 40 mN/m. The dispersion free energy of the first upper surface 221 may be approximately 30 mN/m to approximately 37 mN/m.

The dispersion free energy of the first lower surface 222 may be approximately 30 mN/m to approximately 45 mN/m. The dispersion free energy of the first lower surface 222 may be approximately 30 mN/m to approximately 40 mN/m. The dispersion free energy of the first lower surface 222 may be approximately 25 mN/m to approximately 40 mN/m. The dispersion free energy of the first lower surface 222 may be approximately 30 mN/m to approximately 37 mN/m.

The dispersion free energy of the first side 223 may be approximately 30 mN/m to approximately 45 mN/m. The dispersion free energy of the first side 223 may be approximately 30 mN/m to approximately 40 mN/m. The dispersion free energy of the first side 223 may be approximately 25 mN/m to approximately 40 mN/m. The dispersion free energy of the first side 223 may be approximately 30 mN/m to approximately 37 mN/m.

The dispersion free energy of the first inclined surface 224 may be approximately 30 mN/m to approximately 45 mN/m. The dispersion free energy of the first inclined surface 224 may be approximately 30 mN/m to approximately 40 mN/m. The dispersion free energy of the first inclined surface 224 may be approximately 25 mN/m to approximately 40 mN/m. The dispersion free energy of the first inclined surface 224 may be approximately 30 mN/m to approximately 37 mN/m.

At least one surface of the upper electrode 220 may have polar free energy.

The polar free energy of the first upper surface 221 may be approximately 5 mN/m to approximately 25 mN/m. The polar free energy of the first upper surface 221 may be approximately 7 mN/m to approximately 21 mN/m. The polar free energy of the first upper surface 221 may be approximately 5 mN/m to approximately 15 mN/m. The polar free energy of the first upper surface 221 may be approximately 10 mN/m to approximately 22 mN/m.

The polar free energy of the first lower surface 222 may be approximately 5 mN/m to approximately 25 mN/m. The polar free energy of the first lower surface 222 may be approximately 7 mN/m to approximately 21 mN/m. The polar free energy of the first lower surface 222 may be approximately 5 mN/m to approximately 15 mN/m. The polar free energy of the first lower surface 222 may be approximately 10 mN/m to approximately 22 mN/m.

The polar free energy of the first side 223 may be approximately 5 mN/m to approximately 25 mN/m. The polar free energy of the first side 223 may be approximately 7 mN/m to approximately 21 mN/m. The polar free energy of the first side 223 may be approximately 5 mN/m to approximately 15 mN/m. The polar free energy of the first side 223 may be approximately 10 mN/m to approximately 22 mN/m.

The polar free energy of the first inclined surface 224 may be approximately 5 mN/m to approximately 25 mN/m. The polar free energy of the first inclined surface 224 may be approximately 7 mN/m to approximately 21 mN/m. The polar free energy of the first inclined surface 224 may be approximately 5 mN/m to approximately 15 mN/m. The polar free energy of the first inclined surface 224 may be approximately 10 mN/m to approximately 22 mN/m.

The surface free energy may be the sum of the dispersion free energy and the polar free energy.

More than 90% of each side of the upper electrode 220 may have the first contact angle, the second contact angle, the surface free energy, the dispersion free energy, and the polar free energy within the above-described ranges.

Since the upper electrode 220 has the first contact angle, the second contact angle, the surface free energy, the dispersion free energy, and the polar free energy within the above-described ranges, plasma may be generated and controlled effectively.

In addition, since the upper electrode 220 has the first contact angle, the second contact angle, the surface free energy, the dispersion free energy, and the polar free energy within the above-described ranges, generation of particles that cause defects may be prevented.

In addition, since the upper electrode 220 has the first contact angle, the second contact angle, the surface free energy, the dispersion free energy, and the polar free energy within the above-described ranges, erosion may be suppressed and durability may be improved.

Water or diiodomethane may be sprayed onto a surface to be measured, and by taking images, the first contact angle and the second contact angle may be measured. For example, using a mobile surface analyzer (MSA), which is a mobile surface free energy measurement device manufactured by KRUSS, the surface free energy may be calculated based on measured values. Specifically, after adding 1 microliter of a solvent dropwise, the first contact angle and the second contact angle may be measured at an elapsed time of 4 seconds. Water may be used as a polar free energy solvent, and diiodomethane may be used as a non-polar free energy solvent. A geometric mean combining rule (e.g., Owens, Wendt, Rabel, and Kaelble (WORK) method) may be used to measure the surface free energy, the dispersion free energy, and the polar free energy. For accurate calculations, repeated evaluations are performed more than five times at different positions on the surface of the same specimen. The first contact angle, the second contact angle, the surface free energy, the dispersion free energy, and the polar free energy may be evaluated as the average value of three points excluding the upper and lower limits.

The focus ring 230 according to an embodiment may be a component used in an apparatus for fabricating a semiconductor device. That is, the focus ring 230 may be a component that forms a portion of the semiconductor device fabrication apparatus.

The focus ring 230 may be a component used in a plasma processing apparatus for fabricating a semiconductor device. The focus ring 230 may be a component used in a plasma etching apparatus for selectively etching the semiconductor substrate 30 (See FIG. 7). The semiconductor substrate 30 may be plasma-treated and may include a semiconductor wafer for fabricating a semiconductor device.

The focus ring 230 may be a component that guides plasma and forms a portion of the lower electrode assembly to support the semiconductor substrate 30. The focus ring 230 may be an edge ring disposed at the edge of the lower electrode assembly.

In addition, the focus ring 230 may be a component that forms a portion of an assembly that accommodates the semiconductor substrate 30 and defines the plasma area 114 (See FIG. 7).

FIG. 4 illustrates a focus ring according to an embodiment of the present disclosure. FIG. 5 is a cross-sectional view of the focus ring according to an embodiment of the present disclosure.

Referring to FIGS. 4 and 5, the focus ring 230 according to an embodiment may have an overall ring shape.

The focus ring 230 may include a body portion 237, an inclined portion 238, and a guide portion 239. The body portion 237 may be formed to extend along the periphery of the semiconductor substrate 30. The body portion 237 may be disposed along the periphery of the semiconductor substrate 30. The body portion 237 may have a ring shape.

The inclined portion 238 may be formed to extend from the body portion 237. The inclined portion 238 may be formed to extend inward from the body portion 237. The inclined portion 238 may be formed to extend from the body portion 237 toward the center of the semiconductor substrate 30. The inclined portion 238 may have a ring shape. That is, the inclined portion 238 may be placed on the inner circumferential surface of the body portion 237.

The guide portion 239 may be formed to extend from the inclined portion 238. The guide portion 239 may be formed to extend inward from the inclined portion 238. The guide portion 239 may be formed to extend from the inclined portion 238 toward the center of the semiconductor substrate 30. The guide portion 239 may have a ring shape. At least a portion of the guide portion 239 may be disposed below the semiconductor substrate 30.

The body portion 237, the inclined portion 238, and the guide portion 239 may be formed as one body. That is, the body portion 237, the inclined portion 238, and the guide portion 239 may have an integrated structure rather than a coupled structure. The body portion 237, the inclined portion 238, and the guide portion 239 may be integrally formed of single-crystal silicon.

The focus ring 230 may include a second upper surface 231, a second lower surface 232, and a second side 233.

The second upper surface 231 and the second lower surface 232 may be formed to face each other.

The second upper surface 231 may be included in the body portion 237.

The second lower surface 232 may be flat overall.

The second side 233 extends from the second upper surface 231 to the second lower surface 232. The second side 233 may be the outer circumferential surface of the focus ring 230.

In addition, the focus ring 230 may include the second inclined surface 234. The second inclined surface 234 may extend laterally downward from the second upper surface 231. The second inclined surface 234 may laterally guide plasma process products generated from the semiconductor substrate 30. That is, the second inclined surface 234 may guide process by-products generated by plasma injected into the semiconductor substrate 30 to the outside, thereby improving the efficiency of the semiconductor device fabrication process. In addition, since the second inclined surface 234 may properly guide by-products, the focus ring 230 may prevent other components from being contaminated by by-products of the plasma process.

In addition, the focus ring 230 may further include a guide surface 235. The guide surface 235 is formed to extend from the second inclined surface 234. The guide surface 235 may be formed to extend inward from the second inclined surface 234. The guide surface 235 may be formed to extend below the semiconductor substrate 30. The guide surface 235 may be formed to extend from the second inclined surface 234 to the center of the semiconductor substrate 30. At least a portion of the guide surface 235 may be disposed below the semiconductor substrate 30.

In addition, the focus ring 230 may further include a third side 241. The third side 241 may be formed to extend from the guide surface 235 to the second lower surface 232. The third side 241 may be the inner circumferential surface of the focus ring 230.

In addition, the focus ring 230 may further include a fastening groove formed for fastening with other components.

The focus ring 230 may include single-crystal silicon. The focus ring 230 may include the single-crystal silicon as a main component. The focus ring 230 may include the single-crystal silicon in an amount of approximately 90 wt % or more. The focus ring 230 may include the single-crystal silicon in an amount of approximately 95 wt % or more. The focus ring 230 may include the single-crystal silicon in an amount of approximately 99 wt % or more. The focus ring 230 may be substantially made of single-crystal silicon.

The Si—OH ratio on at least one surface of the focus ring 230 may be approximately 0.16 to approximately 0.28. The Si—OH ratio on at least one surface of the focus ring 230 may be approximately 0.17 to approximately 0.27. The Si—OH ratio on at least one surface of the focus ring 230 may be approximately 0.18 to approximately 0.26. The Si—OH ratio on at least one surface of the focus ring 230 may be approximately 0.19 to approximately 0.26.

One or more of the second upper surface 231, the second lower surface 232, the second side 233, the second inclined surface 234, the guide surface 235, and the third side 241 may have an Si—OH ratio within the above-described range.

Approximately 60% or more of the surface of the focus ring 230 may have an Si—OH ratio within the above-described range. Approximately 70% or more of the surface of the focus ring 230 may have an Si—OH ratio within the above-described range. Approximately 80% or more of the surface of the focus ring 230 may have an Si—OH ratio within the above-described range. Approximately 90% or more of the surface of the focus ring 230 may have an Si—OH ratio within the above-described range. Approximately 95% or more of the surface of the focus ring 230 may have an Si—OH ratio within the above-described range.

Since the surface of the focus ring 230 has an Si—OH ratio within the above-described range, the focus ring 230 may have appropriate surface properties. Accordingly, contaminants may be prevented from remaining on the surface of the focus ring 230.

In addition, since the focus ring 230 has an Si—OH ratio within the above-described range, the focus ring 230 may include a protective film on the surface thereof. Accordingly, the focus ring 230 may be effectively protected from external contaminants.

The focus ring 230 may have a dopant ratio on at least one surface thereof.

The dopant ratio on at least one surface of the focus ring 230 may be less than approximately 0.12. The dopant ratio on at least one surface of the focus ring 230 may be approximately 0.05 to approximately 0.12. The dopant ratio on at least one surface of the focus ring 230 may be approximately 0.01 to approximately 0.12. The dopant ratio on at least one surface of the focus ring 230 may be approximately 0.06 to approximately 0.13.

One or more of the second upper surface 231, the second lower surface 232, the second side 233, the second inclined surface 234, and the third side 241 may have a dopant ratio within the above-described range.

Approximately 60% or more of the surface of the focus ring 230 may have a dopant ratio within the above-described range. Approximately 70% or more of the surface of the focus ring 230 may have a dopant ratio within the above-described range. Approximately 80% or more of the surface of the focus ring 230 may have a dopant ratio within the above-described range. Approximately 90% or more of the surface of the focus ring 230 may have a dopant ratio within the above-described range. Approximately 95% or more of the surface of the focus ring 230 may have a dopant ratio within the above-described range.

Since at least one surface of the focus ring 230 has a dopant ratio within the above-described range, appropriate surface conductivity may be obtained. Accordingly, the focus ring 230 may easily generate plasma. In addition, since at least one surface of the focus ring 230 has a dopant ratio within the above-described range, erosion by plasma may be suppressed. Accordingly, the durability of the focus ring 230 may be improved.

The focus ring 230 may have a body-centered cubic ratio on at least one surface thereof.

The body-centered cubic ratio on at least one surface of the focus ring 230 may be less than approximately 0.01. The body-centered cubic ratio on at least one surface of the focus ring 230 may be less than approximately 0.005. The body-centered cubic ratio on at least one surface of the focus ring 230 may be less than approximately 0.004. The body-centered cubic ratio on at least one surface of the focus ring 230 may be less than approximately 0.001.

One or more of the second upper surface 231, the second lower surface 232, the second side 233, the second inclined surface 234, and the third side 241 may have a body-centered cubic ratio within the above-described range.

Approximately 60% or more of the surface of the focus ring 230 may have a body-centered cubic ratio within the above-described range. Approximately 70% or more of the surface of the focus ring 230 may have a body-centered cubic ratio within the above-described range. Approximately 80% or more of the surface of the focus ring 230 may have a body-centered cubic ratio within the above-described range. Approximately 90% or more of the surface of the focus ring 230 may have a body-centered cubic ratio within the above-described range. Approximately 95% or more of the surface of the focus ring 230 may have a body-centered cubic ratio within the above-described range.

Since at least one surface of the focus ring 230 has a body-centered cubic ratio within the above-described range, surface defect density may decrease. In particular, since at least one surface of the focus ring 230 has a body-centered cubic ratio within the above-described range, the Si-III defect rate of a body-centered cubic structure may be reduced.

Accordingly, the focus ring 230 may suppress defects on the surface thereof. In addition, since at least one surface of the focus ring 230 has a body-centered cubic ratio within the above-described range, erosion by plasma may be suppressed. Accordingly, the durability of the focus ring 230 may be improved.

The focus ring 230 may have a rhombohedral ratio on at least one surface thereof.

The rhombohedral ratio on at least one surface of the focus ring 230 may be less than approximately 0.01. The rhombohedral ratio on at least one surface of the focus ring 230 may be less than approximately 0.005. The rhombohedral ratio on at least one surface of the focus ring 230 may be less than approximately 0.004. The rhombohedral ratio on at least one surface of the focus ring 230 may be less than approximately 0.001.

One or more of the second upper surface 231, the second lower surface 232, the second side 233, the second inclined surface 234, the guide surface 235, and the third side 241 may have a rhombohedral ratio within the above-described range.

Approximately 60% or more of the surface of the focus ring 230 may have a rhombohedral ratio within the above-described range. Approximately 70% or more of the surface of the focus ring 230 may have a rhombohedral ratio within the above-described range. Approximately 80% or more of the surface of the focus ring 230 may have a rhombohedral ratio within the above-described range. Approximately 90% or more of the surface of the focus ring 230 may have a rhombohedral ratio within the above-described range. Approximately 95% or more of the surface of the focus ring 230 may have a rhombohedral ratio within the above-described range.

More than approximately 90% of each side of the focus ring 230 may have an Si—OH ratio, a dopant ratio, a body-centered cubic ratio, or a rhombohedral ratio within the above-described range.

Since at least one surface of the focus ring 230 has a rhombohedral ratio within the above-described range, surface defect density may decrease. In particular, since at least one surface of the focus ring 230 has a rhombohedral ratio within the above-described range, the ratio of Si-XII defects in a rhombohedral structure may be reduced.

Accordingly, the focus ring 230 may suppress defects on the surface thereof. In addition, since at least one surface of the focus ring 230 has a rhombohedral ratio within the above-described range, erosion by plasma may be suppressed. Accordingly, the durability of the focus ring 230 may be improved.

The second upper surface 231 may have Sk roughness. The Sk roughness of the second upper surface 231 may be approximately 0.005 μm to approximately 3 μm. The Sk roughness of the second upper surface 231 may be approximately 0.005 μm to approximately 1 μm. The Sk roughness of the second upper surface 231 may be approximately 0.01 μm to approximately 0.5 μm. The Sk roughness of the second upper surface 231 may be approximately 1 μm to approximately 2 μm. The Sk roughness of the second upper surface 231 may be approximately 1 μm to approximately 1.5 μm.

The second lower surface 232 may have Sk roughness. The Sk roughness of the second lower surface 232 may be approximately 0.005 μm to approximately 3 μm. The Sk roughness of the second lower surface 232 may be approximately 0.005 μm to approximately 1 μm. The Sk roughness of the second lower surface 232 may be approximately 0.01 μm to approximately 0.5 μm. The Sk roughness of the second lower surface 232 may be approximately 1 μm to approximately 2 μm. The Sk roughness of the second lower surface 232 may be approximately 1 μm to approximately 1.5 μm.

The second side 233 and/or the third side 241 may have Sk roughness. The Sk roughness of the second side 233 and/or third side 241 may be greater than the Sk roughness of the second upper surface 231. The Sk roughness of the second side 233 and/or third side 241 may be greater than the Sk roughness of the second lower surface 232. The Sk roughness of the second side 233 and/or third side 241 may be approximately 0.005 μm to approximately 1 μm. The Sk roughness of the second side 233 and/or third side 241 may be approximately 0.01 μm to approximately 0.5 μm. The Sk roughness of the second side 233 and/or third side 241 may be approximately 1 μm to approximately 2 μm. The Sk roughness of the second side 233 and/or third side 241 may be approximately 1 μm to approximately 1.5 μm.

The second inclined surface 234 and/or the guide surface 235 may have Sk roughness. The Sk roughness of the second inclined surface 234 and/or guide surface 235 may be greater than the Sk roughness of the second inclined surface 234 and/or guide surface 235. The Sk roughness of the second inclined surface 234 and/or guide surface 235 may be greater than the Sk roughness of the second inclined surface 234 and/or guide surface 235. The Sk roughness of the second inclined surface 234 and/or guide surface 235 may be approximately 0.005 μm to approximately 1 μm. The Sk roughness of the second inclined surface 234 and/or guide surface 235 may be approximately 0.01 μm to approximately 0.5 μm. The Sk roughness of the second inclined surface 234 and/or guide surface 235 may be approximately 1 μm to approximately 2 μm. The Sk roughness of the second inclined surface 234 and/or guide surface 235 may be approximately 1 μm to approximately 1.5 μm.

Since the second upper surface 231, the second lower surface 232, the 10 second inclined surface 234, or the guide surface 235 has Sk roughness within the above-described range, a microfluidic channel through which plasma flows freely may be included. Accordingly, plasma may flow properly on the second upper surface 231, the second lower surface 232, the second inclined surface 234, or the guide surface 235.

The second upper surface 231 may have Spk roughness. The Spk roughness of the second upper surface 231 may be approximately 0.001 μm to approximately 1 μm. The Spk roughness of the second upper surface 231 may be approximately 0.001 μm to approximately 0.7 μm. The Spk roughness of the second upper surface 231 may be approximately 0.003 μm to approximately 0.7 μm. The Spk roughness of the second upper surface 231 may be approximately 0.1 μm to approximately 1 μm. The Spk roughness of the second upper surface 231 may be approximately 0.001 μm to approximately 0.1 μm.

The second lower surface 232 may have Spk roughness. The Spk roughness of the second lower surface 232 may be approximately 0.001 μm to approximately 0.7 μm. The Spk roughness of the second lower surface 232 may be approximately 0.003 μm to approximately 0.7 μm. The Spk roughness of the second lower surface 232 may be approximately 0.1 μm to approximately 1 μm. The Spk roughness of the second lower surface 232 may be approximately 0.001 μm to approximately 0.1 μm.

The second side 233 and/or the third side 241 may have Spk roughness. The Spk roughness of the second side 233 and/or third side 241 may be greater than the Spk roughness of the second upper surface 231. The Spk roughness of the second side 233 and/or third side 241 may be greater than the Spk roughness of the second lower surface 232. The Spk roughness of the second side 233 and/or third side 241 may be approximately 0.1 μm to approximately 1 μm. The Spk roughness of the second side 233 and/or third side 241 may be approximately 0.08 μm to approximately 0.7 μm. The Spk roughness of the second side 233 and/or third side 241 may be approximately 0.2 μm to approximately 1 μm. The Spk roughness of the second side 233 and/or third side 241 may be approximately 0.2 μm to approximately 0.7 μm.

The second inclined surface 234 and/or the guide surface 235 may have Spk roughness. The Spk roughness of the second inclined surface 234 and/or guide surface 235 may be greater than the Spk roughness of the second upper surface 231. The Spk roughness of the second inclined surface 234 and/or guide surface 235 may be greater than the Spk roughness of the second lower surface 232. The Spk roughness of the second side 233 and/or third side 241 may be greater than the Spk roughness of the second lower surface 232. The Spk roughness of the second side 233 and/or third side 241 may be approximately 0.1 μm to approximately 1 μm. The Spk roughness of the second side 233 and/or third side 241 may be approximately 0.08 μm to approximately 0.7 μm. The Spk roughness of the second side 233 and/or third side 241 may be approximately 0.2 μm to approximately 1 μm. The Spk roughness of the second side 233 and/or third side 241 may be approximately 0.2 μm to approximately 0.7 μm. The Spk roughness of the second inclined surface 234 and/or guide surface 235 may be approximately 0.002 μm to approximately 0.2 μm.

The Spk roughness may be one of important parameters that provides an initial contact area when plasma contacts a surface during a surface etching process. In addition, the Spk roughness may indicate the height of a micro-mountain that may be removed during the plasma process.

Since the second upper surface 231, the second lower surface 232, the second inclined surface 234, or the guide surface 235 has Spk roughness within the above-described range, generation of impurities and process by-products due to micro-mountain etching may be reduced.

The second upper surface 231 may have Svk roughness. The Svk roughness of the second upper surface 231 may be approximately 0.002 μm to approximately 2 μm. The Svk roughness of the second upper surface 231 may be approximately 0.002 μm to approximately 1.7 μm. The Svk roughness of the second upper surface 231 may be approximately 0.004 μm to approximately 1.5 μm. The Svk roughness of the second upper surface 231 may be approximately 0.1 μm to approximately 1.5 μm. The Svk roughness of the second upper surface 231 may be approximately 0.001 μm to approximately 0.2 μm.

The second lower surface 232 may have Svk roughness. The Svk roughness of the second lower surface 232 may be approximately 0.001 μm to approximately 0.7 μm. The Svk roughness of the second lower surface 232 may be approximately 0.002 μm to approximately 1.7 μm. The Svk roughness of the second lower surface 232 may be approximately 0.004 μm to approximately 1.5 μm. The Svk roughness of the second lower surface 232 may be approximately 0.1 μm to approximately 1.5 μm. The Svk roughness of the second lower surface 232 may be approximately 0.001 μm to approximately 0.2 μm.

The second side 233 and/or the third side 241 may have Svk roughness. The Svk roughness of the second side 233 and/or third side 241 may be greater than the Svk roughness of the second upper surface 231. The Svk roughness of the second side 233 and/or third side 241 may be greater than the Svk roughness of the second lower surface 232. The Svk roughness of the second side 233 and/or third side 241 may be approximately 0.15 μm to approximately 1.5 μm. The Svk roughness of the second side 233 and/or third side 241 may be approximately 0.2 μm to approximately 1.7 μm. The Svk roughness of the second side 233 and/or third side 241 may be approximately 0.5 μm to approximately 1.8 μm. The Svk roughness of the second side 233 and/or third side 241 may be approximately 0.4 μm to approximately 1.5 μm.

The second inclined surface 234 and/or the guide surface 235 may have Svk roughness. The Svk roughness of the second inclined surface 234 and/or guide surface 235 may be greater than the Svk roughness of the second upper surface 231. The Svk roughness of the second inclined surface 234 and/or guide surface 235 may be greater than the Svk roughness of the second lower surface 232. The Svk roughness of the second inclined surface 234 and/or guide surface 235 may be approximately 0.15 μm to approximately 1.5 μm. The Svk roughness of the second inclined surface 234 and/or guide surface 235 may be approximately 0.2 μm to approximately 1.7 μm. The Svk roughness of the second inclined surface 234 and/or guide surface 235 may be approximately 0.5 μm to approximately 1.8 μm. The Svk roughness of the second inclined surface 234 and/or guide surface 235 may be approximately 0.4 μm to approximately 1.5 μm.

Since the second upper surface 231, the second lower surface 232, the second inclined surface 234, or the guide surface 235 has Svk roughness within the above-described range, deposition of process by-products in micro-valleys on the surface may be prevented.

The second upper surface 231 may have Sv roughness. The Sv roughness of the second upper surface 231 may be approximately −3 μm to approximately −0.01 μm. The Sv roughness of the second upper surface 231 may be approximately −2.5 μm to approximately −0.01 μm. The Sv roughness of the second upper surface 231 may be approximately −0.1 μm to approximately −0.01 μm. The Sv roughness of the second upper surface 231 may be approximately −2.5 μm to approximately −1 μm. The Sv roughness of the second upper surface 231 may be approximately −3 μm to approximately −0.7 μm.

The second lower surface 232 may have Sv roughness. The Sv roughness of the second lower surface 232 may be approximately −3 μm to approximately −0.01 μm. The Sv roughness of the second lower surface 232 may be approximately −2.5 μm to approximately −0.01 μm. The Sv roughness of the second lower surface 232 may be approximately −0.1 μm to approximately −0.01 μm. The Sv roughness of the second lower surface 232 may be approximately −2.5 μm to approximately −1 μm. The Sv roughness of the second lower surface 232 may be approximately −3 μm to approximately −0.7 μm.

The second side 233 and/or the third side 241 may have Sv roughness. The Sv roughness of the second side 233 and/or third side 241 may be less than the Sv roughness of the second upper surface 231. The Sv roughness of the second side 233 and/or third side 241 may be less than the Sv roughness of the second lower surface 232. The Sv roughness of the second side 233 and/or third side 241 may be approximately −3 μm to approximately −0.1 μm. The Sv roughness of the second side 233 and/or third side 241 may be approximately −2.5 μm to approximately −0.3 μm. The Sv roughness of the second side 233 and/or third side 241 may be approximately −2.5 μm to approximately −0.5 μm. The Sv roughness of the second side 233 and/or third side 241 may be approximately −2.5 μm to approximately −1 μm. The Sv roughness of the second side 233 and/or third side 241 may be approximately −3 μm to approximately −0.7 μm.

The second inclined surface 234 and/or the guide surface 235 may have Sv roughness. The Sv roughness of the second inclined surface 234 and/or guide surface 235 may be less than the Sv roughness of the second upper surface 231. The Sv roughness of the second inclined surface 234 and/or guide surface 235 may be less than the Sv roughness of the second lower surface 232. The Sv roughness of the second inclined surface 234 and/or guide surface 235 may be approximately −3 μm to approximately −0.1 μm. The Sv roughness of the second inclined surface 234 and/or guide surface 235 may be approximately −2.5 μm to approximately −0.3 μm. The Sv roughness of the second inclined surface 234 and/or guide surface 235 may be approximately −2.5 μm to approximately −0.5 μm. The Sv roughness of the second inclined surface 234 and/or guide surface 235 may be approximately −2.5 μm to approximately −1 μm. The Sv roughness of the second inclined surface 234 and/or guide surface 235 may be approximately −3 μm to approximately −0.7 μm.

The second upper surface 231 may have Sz roughness. The Sz roughness of the second upper surface 231 may be approximately 0.01 μm to approximately 6 μm. The Sz roughness of the second upper surface 231 may be approximately 0.02 μm to approximately 1 μm. The Sz roughness of the second upper surface 231 may be approximately 1.5 μm to approximately 6 μm. The Sz roughness of the second upper surface 231 may be approximately 1.5 μm to approximately 5 μm. The Sz roughness of the second upper surface 231 may be approximately 0.03 μm to approximately 0.7 μm.

The second lower surface 232 may have Sz roughness. The Sz roughness of the second lower surface 232 may be approximately 0.01 μm to approximately 6 μm. The Sz roughness of the second lower surface 232 may be approximately 0.02 μm to approximately 1 μm. The Sz roughness of the second lower surface 232 may be approximately 1.5 μm to approximately 6 μm. The Sz roughness of the second lower surface 232 may be approximately 1.5 μm to approximately 5 μm. The Sz roughness of the second lower surface 232 may be approximately 0.03 μm to approximately 0.7 μm.

The second side 233 and/or the third side 241 may have Sz roughness. The Sz roughness of the second side 233 and/or third side 241 may be greater than the Sz roughness of the second upper surface 231. The Sz roughness of the second side 233 and/or third side 241 may be greater than the Sz roughness of the second lower surface 232. The Sz roughness of the second side 233 and/or third side 241 may be approximately 1.5 μm to approximately 6 μm. The Sz roughness of the second side 233 and/or third side 241 may be approximately 1.5 μm to approximately 5 μm. The Sz roughness of the second side 233 and/or third side 241 may be approximately 0.03 μm to approximately 0.7 μm.

The second inclined surface 234 and/or the guide surface 235 may have Sz roughness. The Sz roughness of the second inclined surface 234 and/or guide surface 235 may be greater than the Sz roughness of the second upper surface 231. The Sz roughness of the second inclined surface 234 and/or guide surface 235 may be greater than the Sz roughness of the second lower surface 232. The Sz roughness of the second inclined surface 234 and/or guide surface 235 may be approximately 1.5 μm to approximately 6 μm. The Sz roughness of the second inclined surface 234 and/or guide surface 235 may be approximately 1.5 μm to approximately 5 μm. The Sz roughness of the second inclined surface 234 and/or guide surface 235 may be approximately 0.03 μm to approximately 0.7 μm.

Since the second upper surface 231, the second lower surface 232, the second inclined surface 234, or the guide surface 235 has Sz roughness within the above-described range, plasma flowability may be improved. Accordingly, since the second upper surface 231, the second lower surface 232, the second inclined surface 234, or the guide surface 235 has Sz roughness within the above-described range, deposition of process by-products on the surfaces may be prevented. Accordingly, the focus ring 230 may suppress defects.

The second upper surface 231 may have Sp roughness. The Sp roughness of the second upper surface 231 may be approximately 0.01 μm to approximately 4 μm. The Sp roughness of the second upper surface 231 may be approximately 0.02 μm to approximately 3.5 μm. The Sp roughness of the second upper surface 231 may be approximately 0.8 μm to approximately 3 μm. The Sp roughness of the second upper surface 231 may be approximately 1 μm to approximately 3 μm. The Sp roughness of the second upper surface 231 may be approximately 0.01 μm to approximately 0.7 μm.

The second lower surface 232 may have Sp roughness. The Sp roughness of the second lower surface 232 may be approximately 0.01 μm to approximately 4 μm. The Sp roughness of the second lower surface 232 may be approximately 0.02 μm to approximately 3.5 μm. The Sp roughness of the second lower surface 232 may be approximately 0.8 μm to approximately 3 μm. The Sp roughness of the second lower surface 232 may be approximately 1 μm to approximately 3 μm. The Sp roughness of the second lower surface 232 may be approximately 0.01 μm to approximately 0.7 μm.

The second side 233 and/or the third side 241 may have Sp roughness. The Sp roughness of the second side 233 and/or third side 241 may be greater than the Sp roughness of the second upper surface 231. The Sp roughness of the second side 233 and/or third side 241 may be greater than the Sp roughness of the second lower surface 232. The Sp roughness of the second side 233 and/or third side 241 may be approximately 0.02 μm to approximately 3.5 μm. The Sp roughness of the second side 233 and/or third side 241 may be approximately 0.8 μm to approximately 3 μm. The Sp roughness of the second side 233 and/or third side 241 may be approximately 1 μm to approximately 3 μm. The Sp roughness of the second side 233 and/or third side 241 may be approximately 1 μm to approximately 4 μm.

The second inclined surface 234 and/or the guide surface 235 may have Sp roughness. The Sp roughness of the second inclined surface 234 and/or guide surface 235 may be greater than the Sp roughness of the second upper surface 231. The Sp roughness of the second inclined surface 234 and/or guide surface 235 may be greater than the Sp roughness of the second lower surface 232. The Sp roughness of the second inclined surface 234 and/or guide surface 235 may be approximately 0.02 μm to approximately 3.5 μm. The Sp roughness of the second inclined surface 234 and/or guide surface 235 may be approximately 0.8 μm to approximately 3 μm. The Sp roughness of the second inclined surface 234 and/or guide surface 235 may be approximately 1 μm to approximately 3 μm. The Sp roughness of the second inclined surface 234 and/or guide surface 235 may be approximately 1 μm to approximately 4 μm.

The Sk roughness, the Spk roughness, the Svk roughness, the Sv roughness, the Sz roughness, and the Sp roughness may be measured using a non-contact 3D roughness measuring device. The Sk roughness, the Spk roughness, the Svk roughness, the Sv roughness, the Sz roughness, and the Sp roughness may be calculated by ISO 25178-2. The Sk roughness, the Spk roughness, the Svk roughness, the Sv roughness, the Sz roughness, and the Sp roughness may be measured at 5 to 10 points and may be obtained as an average value of the remaining measurement values excluding the minimum and maximum measurement values.

In addition, the Sk roughness, the Spk roughness, and the Svk roughness may be calculated based on the bearing area curve of the surface of the focus ring 230 obtained using a 3D roughness measuring device. The bearing area curve may be a graph obtained by plotting accumulated data according to height measured for a unit area using a surface roughness measuring device. At this time, the Sk roughness may mean the width of height at a core surface in the accumulated data plot. In addition, the Spk roughness may mean the average height of peaks above the core surface, and the Svk roughness may mean the average depth of valleys below the core surface.

At least one surface of the focus ring 230 may have a reduced peak valley (Spvk) roughness.

The second upper surface 231 may have Spvk roughness. The Spvk roughness of the second upper surface 231 may be approximately 0.005 μm to approximately 2 μm. The Spvk roughness of the second upper surface 231 may be approximately 0.007 μm to approximately 2 μm. The Spvk roughness of the second upper surface 231 may be approximately 0.005 μm to approximately 0.1 μm. The Spvk roughness of the second upper surface 231 may be approximately 0.5 μm to approximately 2 μm. The Spvk roughness of the second upper surface 231 may be approximately 0.7 μm to approximately 1.7 μm.

The second lower surface 232 may have Spvk roughness. The Spvk roughness of the second lower surface 232 may be approximately 0.005 μm to approximately 2 μm. The Spvk roughness of the second lower surface 232 may be approximately 0.007 μm to approximately 2 μm. The Spvk roughness of the second lower surface 232 may be approximately 0.005 μm to approximately 0.1 μm. The Spvk roughness of the second lower surface 232 may be approximately 0.5 μm to approximately 2 μm. The Spvk roughness of the second lower surface 232 may be approximately 0.7 μm to approximately 1.7 μm.

The second side 233 and/or the third side 241 may have Spvk roughness. The Spvk roughness of the second side 233 and/or third side 241 may be greater than the Spvk roughness of the second upper surface 231. The Spvk roughness of the second side 233 and/or third side 241 may be greater than the Spvk roughness of the second lower surface 232. The Spvk roughness of the second side 233 and/or third side 241 may be approximately 0.5 μm to approximately 2 μm. The Spvk roughness of the second side 233 and/or third side 241 may be approximately 0.7 μm to approximately 1.7 μm.

The second inclined surface 234 and/or the guide surface 235 may have Spvk roughness. The Spvk roughness of the second inclined surface 234 and/or guide surface 235 may be greater than the Spvk roughness of the second upper surface 231. The Spvk roughness of the second inclined surface 234 and/or guide surface 235 may be greater than the Spvk roughness of the second lower surface 232. The Spvk roughness of the second inclined surface 234 and/or guide surface 235 may be approximately 0.007 μm to approximately 2 μm. The Spvk roughness of the second inclined surface 234 and/or guide surface 235 may be approximately 0.005 μm to approximately 0.1 μm. The Spvk roughness of the second inclined surface 234 and/or guide surface 235 may be approximately 0.5 μm to approximately 2 μm. The Spvk roughness of the second inclined surface 234 and/or guide surface 235 may be approximately 0.7 μm to approximately 1.7 μm.

The Spvk roughness may be roughness regarding the shapes and sizes of micro-irregularities for example, micro-mountains and micro-valleys. Since the second upper surface 231, the second lower surface 232, the second inclined surface 234, or the guide surface 235 has Spvk roughness within the above-described range, micro-irregularities on the surface may have appropriate shapes and sizes. Accordingly, since the second upper surface 231, the second lower surface 232, the second inclined surface 234, or the guide surface 235 has Spvk roughness within the above-described range, deposition of process by-products in micro-irregularities on the surface or generation of debris causing defects on the surface may be prevented. In addition, since the second upper surface 231, the second lower surface 232, the second inclined surface 234, or the guide surface 235 has Spvk roughness within the above-described range, plasma flowability on the surface may be improved.

At least one surface of the focus ring 230 may have a reduced peak valley ratio (Rpvk).

The second upper surface 231 may have Rpvk. The Rpvk of the second upper surface 231 may be approximately 0.5 to approximately 4. The Rpvk of the second upper surface 231 may be approximately 0.5 to approximately 1.3. The Rpvk of the second upper surface 231 may be approximately 0.5 to approximately 1. The Rpvk of the second upper surface 231 may be approximately 0.6 to approximately 1.2. The Rpvk of the second upper surface 231 may be approximately 0.5 to approximately 1.1.

The second lower surface 232 may have Rpvk. The Rpvk of the second lower surface 232 may be approximately 0.5 to approximately 4. The Rpvk of the second lower surface 232 may be approximately 0.5 to approximately 1.3. The Rpvk of the second lower surface 232 may be approximately 0.5 to approximately 1. The Rpvk of the second lower surface 232 may be approximately 0.6 to approximately 1.2. The Rpvk of the second lower surface 232 may be approximately 0.5 to approximately 1.1.

The second side 233 and/or the third side 241 may have Rpvk. The Rpvk of the second side 233 and/or third side 241 may be approximately 0.5 to approximately 4. The Rpvk of the second side 233 and/or third side 241 may be approximately 0.5 to approximately 1.3. The Rpvk of the second side 233 and/or third side 241 may be approximately 0.5 to approximately 1. The Rpvk of the second side 233 and/or third side 241 may be approximately 0.6 to approximately 1.2. The Rpvk of the second side 233 and/or third side 241 may be approximately 0.5 to approximately 1.1.

The second inclined surface 234 and/or the guide surface 235 may have Rpvk. The Rpvk of the second inclined surface 234 and/or guide surface 235 may be approximately 0.5 to approximately 4. The Rpvk of the second inclined surface 234 and/or guide surface 235 may be approximately 0.5 to approximately 1.3. The Rpvk of the second inclined surface 234 and/or guide surface 235 may be approximately 0.5 to approximately 1. The Rpvk of the second inclined surface 234 and/or guide surface 235 may be approximately 0.6 to approximately 1.2. The Rpvk of the second inclined surface 234 and/or guide surface 235 may be approximately 0.5 to approximately 1.1.

The Rpvk may be the ratio of micro-mountains and micro-valleys at the middle portion of micro-irregularities. Since the second upper surface 231, the second lower surface 232, the second inclined surface 234, or the guide surface 235 has Rpvk in the above-described range, the micro-irregularities in the surface may have appropriate shapes. Accordingly, since the second upper surface 231, the second lower surface 232, the second inclined surface 234, or the guide surface 235 has Rpvk in the above-described range, deposition of process by-products in micro-irregularities on the surface or generation of debris causing defects on the surface may be prevented. In addition, since the second upper surface 231, the second lower surface 232, the second inclined surface 234, or the guide surface 235 has Rpvk in the above-described range, plasma flowability on the surface may be improved.

At least one surface of the focus ring 230 may have total peak valley (Spv) roughness.

The second upper surface 231 may have Spy roughness. The Spy roughness of the second upper surface 231 may be approximately 0.01 μm to approximately 6 μm. The Spy roughness of the second upper surface 231 may be approximately 0.02 μm to approximately 5.5 μm. The Spy roughness of the second upper surface 231 may be approximately 0.01 μm to approximately 1 μm. The Spy roughness of the second upper surface 231 may be approximately 1 μm to approximately 6 μm. The Spy roughness of the second upper surface 231 may be approximately 1.5 μm to approximately 5 μm.

The second lower surface 232 may have Spy roughness. The Spy roughness of the second lower surface 232 may be approximately 0.01 μm to approximately 6 μm. The Spy roughness of the second lower surface 232 may be approximately 0.02 μm to approximately 5.5 μm. The Spy roughness of the second lower surface 232 may be approximately 0.01 μm to approximately 1 μm. The Spy roughness of the second lower surface 232 may be approximately 1 μm to approximately 6 μm. The Spy roughness of the second lower surface 232 may be approximately 1.5 μm to approximately 5 μm.

The second side 233 and/or the third side 241 may have Spy roughness. The Spy roughness of the second side 233 and/or third side 241 may be greater than the Spy roughness of the second upper surface 231. The Spy roughness of the second side 233 and/or third side 241 may be greater than the Spy roughness of the second lower surface 232. The Spy roughness of the second side 233 and/or third side 241 may be approximately 0.02 μm to approximately 5.5 μm. The Spy roughness of the second side 233 and/or third side 241 may be approximately 1 μm to approximately 6 μm. The Spy roughness of the second side 233 and/or third side 241 may be approximately 1.5 μm to approximately 5 μm.

The second inclined surface 234 and/or the guide surface 235 may have Spy roughness. The Spy roughness of the second inclined surface 234 and/or guide surface 235 may be greater than the Spy roughness of the second upper surface 231. The Spy roughness of the second inclined surface 234 and/or guide surface 235 may be greater than the Spy roughness of the second lower surface 232. The Spvk roughness of the second inclined surface 234 and/or guide surface 235 may be approximately 0.007 μm to approximately 2 μm. The Spy roughness of the second inclined surface 234 and/or guide surface 235 may be approximately 0.02 μm to approximately 5.5 μm. The Spy roughness of the second inclined surface 234 and/or guide surface 235 may be approximately 1 μm to approximately 6 μm. The Spy roughness of the second inclined surface 234 and/or guide surface 235 may be approximately 1.5 μm to approximately 5 μm.

The Spy roughness may be roughness representing the overall size of micro-irregularities from a micro-mountain to a micro-valley. Since the second upper surface 231, the second lower surface 232, the second inclined surface 234, or the guide surface 235 has Spy roughness within the above-described range, the micro-irregularities in the surface may have appropriate shapes. Accordingly, since the second upper surface 231, the second lower surface 232, the second inclined surface 234, or the guide surface 235 has Spy roughness within the above-described range, deposition of process by-products in micro-irregularities on the surface or generation of debris causing defects on the surface may be prevented. In addition, since the second upper surface 231, the second lower surface 232, the second inclined surface 234, or the guide surface 235 has Spy roughness within the above-described range, plasma flowability on the surface may be improved.

More than 90% of the surface of the focus ring 230 may have the Sk roughness, the Spk roughness, the Svk roughness, the Sv roughness, the Sz roughness, the Sp roughness, the Spvk roughness, the Spy roughness, and/or the Rpvk within the above-described range.

Since the focus ring 230 has the Sk roughness, the Spk roughness, the Svk roughness, the Sv roughness, the Sz roughness, the Sp roughness, the Spvk roughness, the Spy roughness, and/or the Rpvk within the above-described range, plasma may be generated and controlled effectively.

In addition, since the focus ring 230 has the Sk roughness, the Spk roughness, the Svk roughness, the Sv roughness, the Sz roughness, the Sp roughness, the Spvk roughness, the Spy roughness, and/or the Rpvk within the above-described range, generation of particles that cause defects may be prevented.

In addition, since the focus ring 230 has the Sk roughness, the Spk roughness, the Svk roughness, the Sv roughness, the Sz roughness, the Sp roughness, the Spvk roughness, the Spy roughness, and/or the Rpvk within the above-described range, erosion may be suppressed and durability may be improved.

At least one surface of the focus ring 230 may have a first contact angle with respect to water.

The first contact angle at the second upper surface 231 may be approximately 45° to approximately 74°. The first contact angle at the second upper surface 231 may be approximately 47° to approximately 73°. The first contact angle at the second upper surface 231 may be approximately 60° to approximately 74°. The first contact angle at the second upper surface 231 may be approximately 45° to approximately 60°.

The first contact angle at the second lower surface 232 may be approximately 45° to approximately 74°. The first contact angle at the second lower surface 232 may be approximately 47° to approximately 73°. The first contact angle at the second lower surface 232 may be approximately 60° to approximately 74°. The first contact angle at the second lower surface 232 may be approximately 45° to approximately 60°.

The first contact angle at the second side 233 and/or third side 241 may be less than the first contact angle at the second upper surface 231. The first contact angle at the second side 233 and/or third side 241 may be less than the first contact angle at the second lower surface 232. The first contact angle at the second side 233 and/or third side 241 may be approximately 45° to approximately 73°. The first contact angle at the second side 233 and/or third side 241 may be approximately 45° to approximately 70°. The first contact angle at the second side 233 and/or third side 241 may be approximately 55° to approximately 65°. The first contact angle at the second side 233 and/or third side 241 may be approximately 45° to approximately 60°.

The first contact angle at the second inclined surface 234 and/or guide surface 235 may be less than the first contact angle at the second upper surface 231. The first contact angle at the second inclined surface 234 and/or guide surface 235 may be less than the first contact angle at the second lower surface 232. The first contact angle at the second inclined surface 234 and/or guide surface 235 may be approximately 45° to approximately 730. The first contact angle at the second inclined surface 234 and/or guide surface 235 may be approximately 45° to approximately 70°. The first contact angle at the second inclined surface 234 and/or guide surface 235 may be approximately 55° to approximately 65°. The first contact angle at the second inclined surface 234 and/or guide surface 235 may be approximately 45° to approximately 60°.

At least one surface of the focus ring 230 may have a second contact angle with respect to diiodomethane.

The second contact angle at the second upper surface 231 may be approximately 41° to approximately 57°. The second contact angle at the second upper surface 231 may be approximately 42° to approximately 55°. The second contact angle at the second upper surface 231 may be approximately 45° to approximately 55°. The second contact angle at the second upper surface 231 may be approximately 40° to approximately 50°.

The second contact angle at the second lower surface 232 may be approximately 41° to approximately 57°. The second contact angle at the second lower surface 232 may be approximately 42° to approximately 55°. The second contact angle at the second lower surface 232 may be approximately 45° to approximately 55°. The second contact angle at the second lower surface 232 may be approximately 40° to approximately 50°.

The second contact angle at the second side 233 and/or third side 241 may be approximately 41° to approximately 57°. The second contact angle at the second side 233 and/or third side 241 may be approximately 42° to approximately 55°. The second contact angle at the second side 233 and/or third side 241 may be approximately 45° to approximately 55°. The second contact angle at the second side 233 and/or third side 241 may be approximately 40° to approximately 50°.

The second contact angle at the second inclined surface 234 and/or guide surface 235 may be approximately 41° to approximately 57°. The second contact angle at the second inclined surface 234 and/or guide surface 235 may be approximately 42° to approximately 55°. The second contact angle at the second inclined surface 234 and/or guide surface 235 may be approximately 45° to approximately 55°. The second contact angle at the second inclined surface 234 and/or guide surface 235 may be approximately 40° to approximately 50°.

At least one surface of the focus ring 230 may have surface free energy. The surface free energy of the second upper surface 231 may be approximately 40 mN/m to approximately 65 mN/m. The surface free energy of the second upper surface 231 may be approximately 35 mN/m to approximately 65 mN/m. The surface free energy of the second upper surface 231 may be approximately 40 mN/m to approximately 55 mN/m. The surface free energy of the second upper surface 231 may be approximately 50 mN/m to approximately 65 mN/m.

The surface free energy of the second lower surface 232 may be approximately 40 mN/m to approximately 65 mN/m. The surface free energy of the second lower surface 232 may be approximately 35 mN/m to approximately 65 mN/m. The surface free energy of the second lower surface 232 may be approximately 40 mN/m to approximately 55 mN/m. The surface free energy of the second lower surface 232 may be approximately 50 mN/m to approximately 65 mN/m.

The surface free energy of the second side 233 and/or third side 241 may be greater than the surface free energy of the second upper surface 231. The surface free energy of the second side 233 and/or third side 241 may be greater than the surface free energy of the second lower surface 232. The surface free energy of the second side 233 and/or third side 241 may be approximately 42 mN/m to approximately 65 mN/m. The surface free energy of the second side 233 and/or third side 241 may be approximately 40 mN/m to approximately 65 mN/m. The surface free energy of the second side 233 and/or third side 241 may be approximately 47 mN/m to approximately 65 mN/m. The surface free energy of the second side 233 and/or third side 241 may be approximately 50 mN/m to approximately 65 mN/m.

The surface free energy of the second inclined surface 234 and/or guide surface 235 may be greater than the surface free energy of the second upper surface 231. The surface free energy of the second inclined surface 234 and/or guide surface 235 may be greater than the surface free energy of the second lower surface 232. The surface free energy of the second inclined surface 234 and/or guide surface 235 may be approximately 42 mN/m to approximately 65 mN/m. The surface free energy of the second inclined surface 234 and/or guide surface 235 may be approximately 47 mN/m to approximately 65 mN/m. The surface free energy of the second inclined surface 234 and/or guide surface 235 may be approximately 50 mN/m to approximately 65 mN/m. The surface free energy of the second inclined surface 234 and/or guide surface 235 may be approximately 40 mN/m to approximately 65 mN/m.

At least one surface of the focus ring 230 may have dispersion free energy.

The dispersion free energy of the second upper surface 231 may be approximately 30 mN/m to approximately 45 mN/m. The dispersion free energy of the second upper surface 231 may be approximately 30 mN/m to approximately 40 mN/m. The dispersion free energy of the second upper surface 231 may be approximately 25 mN/m to approximately 40 mN/m. The dispersion free energy of the second upper surface 231 may be approximately 30 mN/m to approximately 37 mN/m.

The dispersion free energy of the second lower surface 232 may be approximately 30 mN/m to approximately 45 mN/m. The dispersion free energy of the second lower surface 232 may be approximately 30 mN/m to approximately 40 mN/m. The dispersion free energy of the second lower surface 232 may be approximately 25 mN/m to approximately 40 mN/m. The dispersion free energy of the second lower surface 232 may be approximately 30 mN/m to approximately 37 mN/m.

The dispersion free energy of the second side 233 and/or third side 241 may be approximately 30 mN/m to approximately 45 mN/m. The dispersion free energy of the second side 233 and/or third side 241 may be approximately 30 mN/m to approximately 40 mN/m. The dispersion free energy of the second side 233 and/or third side 241 may be approximately 25 mN/m to approximately 40 mN/m. The dispersion free energy of the second side 233 and/or third side 241 may be approximately 30 mN/m to approximately 37 mN/m.

The dispersion free energy of the second inclined surface 234 and/or guide surface 235 may be approximately 30 mN/m to approximately 45 mN/m. The dispersion free energy of the second inclined surface 234 and/or guide surface 235 may be approximately 30 mN/m to approximately 40 mN/m. The dispersion free energy of the second inclined surface 234 and/or guide surface 235 may be approximately 25 mN/m to approximately 40 mN/m. The dispersion free energy of the second inclined surface 234 and/or guide surface 235 may be approximately 30 mN/m to approximately 37 mN/m.

One surface of the focus ring 230 may have polar free energy.

The polar free energy of the second upper surface 231 may be approximately 5 mN/m to approximately 25 mN/m. The polar free energy of the second upper surface 231 may be approximately 7 mN/m to approximately 21 mN/m. The polar free energy of the second upper surface 231 may be approximately 5 mN/m to approximately 15 mN/m. The polar free energy of the second upper surface 231 may be approximately 10 mN/m to approximately 22 mN/m.

The polar free energy of the second lower surface 232 may be approximately 5 mN/m to approximately 25 mN/m. The polar free energy of the second lower surface 232 may be approximately 7 mN/m to approximately 21 mN/m. The polar free energy of the second lower surface 232 may be approximately 5 mN/m to approximately 15 mN/m. The polar free energy of the second lower surface 232 may be approximately 10 mN/m to approximately 22 mN/m.

The polar free energy of the second side 233 and/or third side 241 may be approximately 5 mN/m to approximately 25 mN/m. The polar free energy of the second side 233 and/or third side 241 may be approximately 7 mN/m to approximately 21 mN/m. The polar free energy of the second side 233 and/or third side 241 may be approximately 5 mN/m to approximately 15 mN/m. The polar free energy of the second side 233 and/or third side 241 may be approximately 10 mN/m to approximately 22 mN/m.

The polar free energy of the second inclined surface 234 and/or guide surface 235 may be approximately 5 mN/m to approximately 25 mN/m. The polar free energy of the second inclined surface 234 and/or guide surface 235 may be approximately 7 mN/m to approximately 21 mN/m. The polar free energy of the second inclined surface 234 and/or guide surface 235 may be approximately 5 mN/m to approximately 15 mN/m. The polar free energy of the second inclined surface 234 and/or guide surface 235 may be approximately 10 mN/m to approximately 22 mN/m.

More than 90% of the surface of the focus ring 230 may have the first contact angle, the second contact angle, the surface free energy, the dispersion free energy, and/or the polar free energy within the above-described range.

Since the focus ring 230 has the first contact angle, the second contact angle, the surface free energy, the dispersion free energy, and/or the polar free energy within the above-described range, plasma may be generated and controlled effectively.

In addition, since the focus ring 230 has the first contact angle, the second contact angle, the surface free energy, the dispersion free energy, and/or the polar free energy within the above-described range, generation of particles that cause defects may be prevented.

In addition, since the focus ring 230 has the first contact angle, the second contact angle, the surface free energy, the dispersion free energy, and/or the polar free energy within the above-described range, erosion may be suppressed, and durability may be improved.

The upper electrode 220 and focus ring 230 according to an embodiment may be manufactured by the following process.

First, raw materials for the upper electrode 220 and the focus ring 230 are prepared.

The raw materials may include silicon. The silicon may have high purity. The silicon may have a purity of approximately 99.999999% or higher.

The raw materials may include a dopant. The dopant may include an n-type dopant such as nitrogen or phosphorus or a p-type dopant such as boron or aluminum.

An ingot may be manufactured using the raw materials. That is, to manufacture the electrode and the focus ring 230 according to an embodiment, a single-crystal silicon ingot may be manufactured.

A single-crystal silicon ingot manufacturing apparatus according to an embodiment may include a chamber, a crucible, a heater, and a lifting means. For example, the single-crystal growth apparatus according to an embodiment may include a chamber, a crucible that is provided inside the chamber and accommodates silicon melt, a heater that is provided inside the chamber and heats the crucible, and a lifting means with a seed crystal attached to one end.

The chamber may provide a space where certain processes are performed to grow a single-crystal silicon ingot for producing components for fabricating the semiconductor device.

A radiant insulator may be installed on the inner wall of the chamber to prevent heat of the heater from being released to the side wall of the chamber.

To control oxygen concentration during single-crystal silicon growth, various factors such as pressure conditions inside the quartz crucible may be adjusted. For example, according to an embodiment, to control oxygen concentration, argon gas or the like may be injected into the chamber of the single-crystal silicon growth apparatus and discharged to the bottom.

The crucible may be provided inside the chamber to contain silicon melt and may be made of quartz. A crucible support made of graphite may be provided on the outside of the crucible to support the crucible. The crucible support may be fixed on a rotating shaft, and the rotating shaft is rotated by a driving means to rotate and lift the crucible so that a solid-liquid interface maintains the same height.

The heater may be provided inside the chamber to heat the crucible. For example, the heater may have a cylindrical structure surrounding the crucible support. The heater may melt high-purity polycrystalline silicon mass loaded in the crucible to form silicon melt.

The single-crystal silicon ingot may be formed by the Czochralski (CZ) method. The Czochralski (CZ) method is a method of growing a crystal by immersing a single-crystal seed in silicon melt and then slowly pulling the seed up.

The single-crystal silicon ingot may be sliced to a thickness of approximately 3 mm to approximately 25 mm. The slicing process may be performed using a wire saw. The wire saw may include a wire and diamond particles bonded around the wire.

Accordingly, by the slicing process, a single-crystal silicon plate is manufactured.

Then, the single-crystal silicon plate may be subjected to a chamfering process. That is, the edges of the single-crystal silicon plate are ground. Accordingly, a first chamfered surface extending from the upper surface of the single-crystal plate and sloping with respect to the upper surface and a second chamfered surface extending from the lower surface of the single-crystal plate and sloping with respect to the lower surface are formed.

The chamfering process may be performed using a hand grinder.

The single-crystal silicon plate may be subjected to a grinding process.

The single-crystal silicon plate may be placed between an upper surface plate and a lower surface plate. The single-crystal silicon plate may move relative to the upper and lower surface plates, so that the single-crystal silicon plate is ground.

The outer circumferential surface of the single-crystal silicon plate may be machined. Machining of the outer circumferential surface may be performed using a second grinder.

A single-crystal silicon plate with the outer circumferential surface machined may be subjected to shape machining. Shape machining of the single-crystal silicon plate may be performed using a third grinder.

Using the third grinder, the approximate outline of the focus ring 230 and/or upper electrode 220 may be formed. Cutting may be performed using the third grinder to form an open area in a central part. In addition, using the third grinder, the approximate outlines of the inclined portion 238 and guide portion 239 may be formed.

The number of rotations of the third grinder head may be approximately 1500 rpm to approximately 8000 rpm. The number of rotations of the third grinder head may be approximately 1700 rpm to approximately 7500 rpm. The number of rotations of the third grinder head may be approximately 1000 rpm to approximately 6500 rpm.

The third grinder head may have approximately 100 mesh to approximately 2000 mesh. The third grinder head may have approximately 500 mesh to approximately 2000 mesh. The third grinder head may have approximately 1000 mesh to approximately 2000 mesh.

In the shape machining process, the feed may be approximately 1 mm/min to approximately 15 mm/min. In the shape machining process, the feed may be approximately 2 mm/min to approximately 10 mm/min. In the shape machining process, the feed may be approximately 3 mm/min to approximately 8 mm/min.

By the shape machining, the stepped portion, the first inclined surface 224, and the second inclined surface 234 may be formed. In addition, by the shape machining, a fastening groove may be formed for fastening with other components. By the shape machining, an open area for seating the semiconductor substrate 30 may be formed in the focus ring 230. In addition, by the shape machining, the inclined portion 238 and the guide portion 239 may be formed in the focus ring 230.

The through-holes 226 may be formed in the single-crystal silicon plate.

The through-holes 226 may be formed using a drill.

The through-holes 226 may be formed by electric discharge machining.

By the shape machining process and/or the process of forming the through-holes 226, an unprocessed focus ring and/or an unprocessed upper electrode may be formed.

The unprocessed focus ring and/or the unprocessed upper electrode may be subjected to a wrapping process.

The unprocessed focus ring and/or the unprocessed upper electrode may be placed between an upper surface plate and a lower surface plate, and the unprocessed focus ring and/or the unprocessed upper electrode may move relative to the upper surface plate and the lower surface plate, so that the unprocessed focus ring and/or the unprocessed upper electrode are wrapped.

The unprocessed focus ring and/or the unprocessed upper electrode may be rotated relative to the upper surface plate and/or the lower surface plate at a speed of approximately 5 rpm to approximately 25 rpm.

In the wrapping process, the upper surface plate and the lower surface plate may have approximately 800 mesh to approximately 1800 mesh.

In the wrapping process, the pressure of the upper surface plate and lower surface plate may be approximately 60 psi to approximately 200 psi.

In the single-crystal silicon plate that has been subjected to the grinding process, the Ra roughness of the ground upper and lower surfaces may be approximately 0.1 μm to approximately 0.2 μm.

The unprocessed focus ring and the unprocessed upper electrode may be surface-processed by a wet etching process.

The surfaces of the unprocessed focus ring and the unprocessed upper electrode may be etched using an etchant for the wet etching process. The etchant may include deionized water and an acid. The etchant may include an acid such as sulfuric acid or hydrofluoric acid. The etchant may include one or more salts consisting of ammonium hydrogen fluoride, ammonium sulfate, and ammonium sulfamate.

Based on a total weight, the etchant may include deionized water in an amount of approximately 20 wt % to approximately 50 wt %.

Based on 100 parts by weight of the deionized water, the etchant may include the acid in an amount of approximately 70 parts by weight to approximately 200 parts by weight. Based on 100 parts by weight of the deionized water, the etchant may include the acid in an amount of approximately 90 parts by weight to approximately 150 parts by weight.

Based on 100 parts by weight of the deionized water, the etchant may include the ammonium hydrogen fluoride in an amount of approximately 15 parts by weight to approximately 45 parts by weight. Based on 100 parts by weight of the deionized water, the etchant may include the ammonium hydrogen fluoride in an amount of approximately 17 parts by weight to approximately 30 parts by weight.

Based on 100 parts by weight of the deionized water, the etchant may include the ammonium sulfate in an amount of approximately 15 parts by weight to approximately 45 parts by weight. Based on 100 parts by weight of the deionized water, the etchant may include the ammonium sulfate in an amount of approximately 17 parts by weight to approximately 30 parts by weight.

Based on 100 parts by weight of the deionized water, the etchant may include the ammonium sulfamate in an amount of approximately 5 parts by weight to approximately 20 parts by weight. Based on 100 parts by weight of the deionized water, the etchant may include the ammonium sulfamate in an amount of approximately 5 parts by weight to approximately 15 parts by weight.

The unprocessed focus ring and/or the unprocessed upper electrode may be immersed in the etchant to perform the etching process. The immersion time may be approximately 10 minutes to approximately 100 minutes. The immersion time may be approximately 5 minutes to approximately 20 minutes. The immersion time may be approximately 10 minutes to approximately 30 minutes.

Since the etching process is performed using the etchant having the above-described composition for the immersion time within the range, the surfaces of the unprocessed focus ring and the unprocessed upper electrode may be appropriately etched. Accordingly, the focus ring 230 according to an embodiment and the upper electrode 220 according to an embodiment may have appropriate surface properties.

The unprocessed focus ring and/or the unprocessed upper electrode may be surface-treated by a polishing process.

A polishing pad may be used in the polishing process. The Shore C hardness of the polishing pad may be approximately 50 to approximately 90. The polishing pad may be a suede-type or non-woven fabric-type pad.

In the polishing process, a polishing slurry may be used. The polishing slurry may contain deionized water and colloidal silica.

Based on a total weight, the polishing slurry may include the colloidal silica in an amount of approximately 20 wt % to approximately 50 wt %. Based on a total weight, the polishing slurry may include the colloidal silica in an amount of approximately 30 wt % to approximately 45 wt %.

The average particle diameter of the colloidal silica may be approximately 20 nm to approximately 100 nm. The average particle diameter of the colloidal silica may be approximately 50 nm to approximately 100 nm. The average particle diameter of the colloidal silica may be approximately 60 nm to approximately 85 nm.

The pH of the polishing slurry may be approximately 8.5 to approximately 11. The pH of the polishing slurry may be approximately 9.0 to approximately 10.5.

In the polishing process, polishing pressure may be approximately 200 psi to approximately 350 psi.

In addition, in the polishing process, the rotation speed of the surface plate may be approximately 6 rpm to approximately 15 rpm.

In addition, the polishing process time may be approximately 60 minutes to approximately 75 minutes.

The focus ring and upper electrode that have been subjected to the polishing process are cleaned using a cleaning solution.

The cleaning solution may include deionized water, hydrogen peroxide, and ammonia.

Based on a total weight, the cleaning solution may include deionized water in an amount of approximately 90 wt % to approximately 97 wt %.

Based on 100 parts by weight of the deionized water, the cleaning solution may include the hydrogen peroxide in an amount of approximately 1 part by weight to approximately 10 parts by weight. Based on 100 parts by weight of the deionized water, the cleaning solution may include the hydrogen peroxide in amount of approximately 1 part by weight to approximately 7 parts by weight.

Based on 100 parts by weight of the deionized water, the cleaning solution may include ammonia in an amount of approximately 1 part by weight to approximately 8 parts by weight. Based on 100 parts by weight of the deionized water, the cleaning solution may include ammonia in an amount of approximately 1 part by weight to approximately 5 parts by weight.

The focus ring 230 and the upper electrode may be immersed in the cleaning solution for approximately 20 minutes to approximately 30 minutes.

In addition, the cleaning solution may be sprayed onto the focus ring 230 and/or the upper electrode to perform the cleaning process.

In addition, the cleaning solution may be sprayed inside the through-holes 226, and the inside of the through-holes 226 may be cleaned.

Then, the focus ring 230 and/or the upper electrode may be cleaned using deionized water.

Then, the cleaned focus ring 230 and/or the upper electrode may be surface-treated.

The focus ring 230 and/or the upper electrode 220 may be surface-treated under oxygen atmosphere. The focus ring 230 and/or the upper electrode 220 may be surface-treated under atmospheric atmosphere.

In the surface treatment process, thermal energy and/or light energy may be applied to the surface of the focus ring 230 and/or the upper electrode 220.

In the surface treatment process, the focus ring 230 and/or the upper electrode 220 may be heat-treated under oxygen atmosphere. The focus ring 230 and/or the upper electrode 220 may be heat-treated at a temperature of approximately 100° C. to approximately 200° C. for approximately 30 seconds to approximately 5 minutes under atmospheric atmosphere.

In addition, in the surface treatment process, the focus ring 230 and/or the upper electrode 220 may be irradiated with light under oxygen atmosphere. The surface of the focus ring 230 and/or the upper electrode 220 may be irradiated with light for approximately 30 seconds to approximately 5 minutes under atmospheric atmosphere.

The spectrum of light used in the surface treatment process may have a first peak in the wavelength range of approximately 400 nm to approximately 500 nm. The first peak may be located between approximately 420 nm and approximately 480 nm.

In addition, the spectrum of light used in the surface treatment process may have a second peak in the wavelength range of approximately 500 nm to approximately 650 nm. The second peak may be located between approximately 550 nm and approximately 650 nm.

In addition, the spectrum of light used in the surface treatment process may have a maximum peak in the wavelength range of approximately 300 nm to approximately 320 nm.

In addition, the spectrum of light used in the surface treatment process may have a maximum peak in the wavelength range of approximately 360 nm to approximately 380 nm.

The light source used in the surface treatment process may be a UVA lamp. The light source used in the surface treatment process may be a UVB lamp. The light source used in the surface treatment process may be a white LED.

The output of the light source used in the surface treatment process may be approximately 20 W to approximately 200 W. The output of the light source used in the surface treatment process may be approximately 25 W to approximately 160 W.

In the surface treatment process, the surface of the focus ring 230 and/or the upper electrode 220 may be irradiated with light having a roughness of approximately 30 lux to approximately 10000 lux. In the surface treatment process, the surface of the focus ring 230 and/or the upper electrode 220 may be irradiated with light having a roughness of approximately 50 lux to approximately 5000 lux. In the surface treatment process, the surface of the focus ring 230 and/or the upper electrode 220 may be irradiated with light having a roughness of approximately 50 lux to approximately 2000 lux.

The light irradiation process time may be approximately 30 seconds to approximately 10 minutes. The light irradiation process time may be approximately 1 minute to approximately 5 minutes. The light irradiation process time may be approximately 30 seconds to approximately 3 minutes.

Then, after surface treatment of the focus ring 230 and/or the upper electrode 220 is completed, the focus ring 230 and/or the upper electrode 220 may be sealed. After surface treatment of the focus ring 230 and/or the upper electrode 220 is completed, the focus ring 230 and/or the upper electrode 220 may be sealed to block external oxygen. After surface treatment of the focus ring 230 and/or the upper electrode 220 is completed, the focus ring 230 and/or the upper electrode 220 may be sealed, and the sealed interior may be filled with nitrogen.

The component for a semiconductor device fabrication apparatus according to an embodiment has a surface having an Si—OH ratio of 0.16 to 0.28. Since the surface contains an appropriate amount of Si—OH, the inside of the component for a semiconductor device fabrication apparatus according to an embodiment may be effectively protected from external contamination.

In addition, since the surface of the component for a semiconductor device fabrication apparatus according to an embodiment contains Si—OH within the above-described range, external contaminants such as particles may be prevented from adhering to the part.

Accordingly, the component for a semiconductor device fabrication apparatus according to an embodiment may prevent external and internal contamination and prevent contaminants from transferring into the chamber of a semiconductor device fabrication apparatus. Accordingly, the component for a semiconductor device fabrication apparatus according to an embodiment may minimize defects generated when the semiconductor substrate 30 is fabricated.

In addition, the surface of the component for a semiconductor device fabrication apparatus according to an embodiment may include an appropriate dopant peak. Accordingly, the component for a semiconductor device fabrication apparatus according to an embodiment may have appropriate electrical properties and may minimize defects generated by the dopant.

In addition, the component for a semiconductor device fabrication apparatus according to an embodiment has a surface having a low body-centered cubic ratio and a low rhombohedral ratio. Accordingly, the frequency of crystal defects on the surface of the component for a semiconductor device fabrication apparatus according to an embodiment may be low.

Accordingly, the component for a semiconductor device fabrication apparatus according to an embodiment may prevent excessive wear caused by the crystal defects in the process for fabricating the semiconductor substrate 30. Accordingly, the component for a semiconductor device fabrication apparatus according to an embodiment may suppress generation of particles in a process chamber due to the excessive wear. Accordingly, the component for a semiconductor device fabrication apparatus according to an embodiment may prevent defects generated when the semiconductor substrate 30 is fabricated. In addition, since excessive wear is suppressed, the component for a semiconductor device fabrication apparatus according to an embodiment may have improved durability.

FIG. 6 is a diagram for describing a semiconductor device fabrication apparatus according to an embodiment of the present disclosure. FIG. 7 is a cross-sectional view of a plasma region-confined assembly according to an embodiment of the present disclosure.

The elements in FIG. 7 are 210: COVER, 220: UPPER ELECTRODE, 230: FOCUS RING, 250: FIRST INSULATING RING, 240: SECOND INSULATING RING, 260: THIRD INSULATING RING, and 270: ELECTROSTATIC CHUCK

Referring to FIGS. 6 and 7, the semiconductor device fabrication apparatus 10 according to an embodiment may include a plasma reactor 102 having a plasma processing chamber 104 therein. In addition, the semiconductor device fabrication apparatus according to an embodiment may further include a plasma region-confined assembly 20 disposed inside the plasma processing chamber 104. The plasma processing chamber 104 may be substantially the same as the plasma region-confined assembly 20.

In addition, the semiconductor device fabrication apparatus according to an embodiment may include a matching network 108. The semiconductor device fabrication apparatus according to an embodiment may include a plasma power supply 106 tuned by the matching network 108. The plasma power supply 106 may provide inductively coupled power to the plasma reactor 102. Accordingly, plasma may be created within the plasma region-confined assembly 20. More specifically, the plasma power supply 106 may supply power to a TCP coil 110 located near a power window 112 so that the plasma is generated. The TCP coil 110 may be configured to generate the plasma with a uniform diffusion profile within the plasma region-confined assembly 20. For example, the TCP coil 110 may be configured to produce a toroidal power distribution within the plasma-confined assembly.

In the power window 112, the TCP coil 110 may be spaced apart from the plasma processing chamber 104 at a certain interval. In addition, the TCP coil 110 may supply energy to the plasma processing chamber 104 while being spaced apart from the plasma processing chamber 104.

The semiconductor device fabrication apparatus according to an embodiment may further include a bias voltage power supply 116 tuned by the matching network 118.

The bias voltage power supply 116 may set a bias voltage on the semiconductor substrate 30 through an electrostatic chuck 270 (See FIG. 8). That is, the bias voltage power supply 116 may supply power for setting the bias voltage to the semiconductor substrate 30.

The semiconductor device fabrication apparatus according to an embodiment may further include a controller 124. The controller 124 may control operation of the plasma power supply 106, a gas source supply unit 130, and the bias voltage power supply 116.

For example, the plasma power supply 106 and the bias voltage power supply 116 may be configured to operate at specific radio frequencies, such as approximately 13.56 MHz, 27 MHz, 2 MHz, 60 MHz, 400 KHz, 2.54 GHz, or combinations thereof.

The plasma power supply 106 and the bias voltage power supply 116 may adjust the amount of supplied power to achieve target process performance. For example, the plasma power supply 106 may supply power in the range of approximately 50 W to approximately 5000 W. The bias voltage power supply 116 may supply a bias voltage in the range of approximately 20 V to approximately 2000 V.

In addition, the semiconductor device fabrication apparatus according to an embodiment may further include the gas source supply unit 130. The gas source supply unit 130 may be fluidly connected to the plasma region-confined assembly 20 through a gas inlet such as a gas injector 140.

In addition, the semiconductor device fabrication apparatus according to an embodiment may include a pressure control valve 142 and pump 144, which serve to maintain a specific pressure within the plasma processing chamber 104. By-products are removed from the plasma process-confined chamber 104 by the pressure control valve 142 and the pump 144. The pressure control valve 142 may maintain process pressure below 1 Torr during processing.

As shown in FIG. 8, the plasma region-confined assembly 20 may include a cover 210, the upper electrode 220, the focus ring 230, a first insulating ring 250, a second insulating ring 240, a third insulating ring 260, and the electrostatic chuck 270.

The cover 210 may be placed on the outer portion of the plasma area 114. The cover 210 may be formed to extend along the outer portion of the plasma area 114. The cover 210 may be disposed along the periphery of the plasma area 114.

The cover 210 may support the upper electrode 220. The cover 210 may be fastened to the upper electrode 220. In addition, the cover 210 may be fastened to the second insulating ring 240. In addition, the cover 210 may be fastened to the third insulating ring 260. The cover 210 may support the third insulating ring 260.

The cover 210 may contain silicon. The cover 210 may be made of silicon. The cover 210 may include polysilicon or single-crystal silicon. The cover 210 may be made of polysilicon.

The cover 210 may include a discharge portion 280 through which process by-products generated in the plasma area 114 are discharged. The discharge portion 280 may be connected to the plasma area 114.

The upper electrode 220 and the focus ring 230 may have the same properties as described above.

The upper electrode 220 may be seated on the cover 210. The upper electrode 220 may be seated on the cover 210. The upper electrode 220 may be fastened to the cover 210. The upper electrode 220 may be coupled to the cover 210.

The upper electrode 220 is placed on the plasma area 114. The upper electrode 220 may entirely cover the upper portion of the plasma area 114. The upper electrode 220 may be formed to face the semiconductor substrate 30, and the plasma area 114 is disposed therebetween.

The focus ring 230 may be formed to extend along the periphery of the semiconductor substrate 30. The focus ring 230 may be placed on the electrostatic chuck 270. The focus ring 230 may extend along the perimeter of the plasma area 114. The focus ring 230 may be placed inside the first insulating ring 250.

The focus ring 230 may surround a portion where the semiconductor substrate 30 is placed. The focus ring 230 may form a space 236 where the semiconductor substrate 30 is placed. The focus ring 230 may be placed at an edge portion of the semiconductor substrate 30.

The first insulating ring 250 may surround the focus ring 230. The first insulating ring 250 may surround the electrostatic chuck 270. The first insulating ring 250 may extend along the outer circumferential surface of the electrostatic chuck 270. The first insulating ring 250 may extend along the outer circumferential surface of the focus ring 230. The first insulating ring 250 may cover the outer circumferential surface of the focus ring 230 and the outer circumferential surface of the electrostatic chuck 270.

The first insulating ring 250 is disposed between the cover 210 and the focus ring 230. In addition, the first insulating ring 250 may be disposed between the cover 210 and the electrostatic chuck 270.

In addition, the first insulating ring 250 may have high electrical resistance. That is, the first insulating ring 250 may have high insulating properties. Accordingly, the first insulating ring 250 may insulate between the focus ring 230 and the cover 210. In addition, the first insulating ring 250 may insulate between the electrostatic chuck 270 and the cover 210.

The first insulating ring 250 may contain a material that has high electrical resistance and high etch resistance. The first insulating ring 250 may include quartz. The first insulating ring 250 may include melt quartz and/or synthetic quartz.

The first insulating ring 250 may be made of quartz. The first insulating ring 250 may be made of quartz having a purity of approximately 99.99% or more.

The second insulating ring 240 is disposed outside the first insulating ring 250. The second insulating ring 240 may surround the outer circumferential surface of the first insulating ring 250. The second insulating ring 240 may be formed to extend along the periphery of the first insulating ring 250.

The second insulating ring 240 may reinforce the insulating properties of the first insulating ring 250. The second insulating ring 240 may insulate between the focus ring 230 and the cover 210. In addition, the second insulating ring 240 may insulate between the electrostatic chuck 270 and the cover 210.

The second insulating ring 240 may include a material that has high electrical resistance and high etch resistance. The second insulating ring 240 may include quartz. The second insulating ring 240 may include melt quartz and/or synthetic quartz.

The second insulating ring 240 may be made of quartz. The second insulating ring 240 may be made of quartz having a purity of approximately 99.99% or more.

The third insulating ring 260 may be placed under the cover 210. The third insulating ring 260 may be placed outside the first insulating ring 250. The third insulating ring 260 may extend along the outer circumferential surface of the first insulating ring 250. The third insulating ring 260 may be placed outside the electrostatic chuck 270.

The third insulating ring 260 may be disposed around the discharge portion 280. The discharge portion 280 may be an exhaust port for discharging process by-products generated in the plasma area 114.

The third insulating ring 260 may include a material that has high electrical resistance and has high etch resistance. The third insulating ring 260 may include quartz. The third insulating ring 260 may include melt quartz and/or synthetic quartz.

The third insulating ring 260 may be made of quartz. The third insulating ring 260 may be made of quartz having a purity of approximately 99.99% or more.

The semiconductor device fabrication apparatus according to an embodiment may treat the semiconductor substrate 30 with plasma. The semiconductor device fabrication apparatus according to an embodiment may fabricate a semiconductor device by treating the semiconductor substrate 30 with plasma.

The semiconductor substrate 30 may include a wafer, an etch target layer disposed on the wafer, and a mask pattern disposed on the etch target layer.

The etch target layer may be a conductive layer including a metal layer. The etch target layer may be a dielectric layer containing an oxide film.

The mask pattern may selectively expose the etch target layer. The mask pattern may include a photoresist layer. The photoresist layer may be patterned by light.

To treat the semiconductor substrate 30 with plasma, the semiconductor substrate 30 is placed on the electrostatic chuck 270. In addition, the semiconductor substrate 30 may be disposed within the focus ring 230. The semiconductor substrate 30 may be placed on the guide portion 239.

Then, plasma may be sprayed onto the semiconductor substrate 30. The plasma is formed by a gas injected through the upper electrode 220 and may be injected onto the semiconductor substrate 30.

The gas source may include hydrogen gas (H₂), nitrogen gas (N₂), and fluorine-based gas. The fluorine-based gas may include hydrogen fluoride or fluorocarbon (CHₓF₄₋ₓ, x is an integer from 1 to 3).

The flow ratio of the hydrogen gas and the nitrogen gas may be approximately 3:1 to approximately 7:1. In addition, the flow ratio of the hydrogen and the fluorine-based gas may be approximately 10:1 to approximately 100:1.

By means of the plasma, the etch target layer may be selectively etched. Accordingly, a conductive pattern or insulating pattern may be formed on the wafer.

Since the focus ring 230 and the upper electrode 220 have the above-described characteristics, the semiconductor device fabrication apparatus according to an embodiment may prevent defects occurring during the process of fabricating the semiconductor substrate 30.

The component for a semiconductor device fabrication apparatus according to an embodiment may include a surface having a water contact angle of 45° to 74° and a diiodomethane contact angle of 37° to 57°. Since the surface has an appropriate water contact angle and diiodomethane contact angle, the inside of the component for a semiconductor device fabrication apparatus according to an embodiment may be effectively protected from external contamination.

In addition, since the surface of the component for a semiconductor device fabrication apparatus according to an embodiment has a water contact angle and a diiodomethane contact angle within the above-described ranges, external contaminants such as particles may be prevented from attaching to the part.

Accordingly, the component for a semiconductor device fabrication apparatus according to an embodiment may prevent external and internal contamination and prevent contaminants from transferring into the chamber of a semiconductor device fabrication apparatus. Accordingly, the component for a semiconductor device fabrication apparatus according to an embodiment may minimize defects that occur in a semiconductor device fabrication process.

In addition, the surface of the component for a semiconductor device fabrication apparatus according to an embodiment has appropriate surface energy. Accordingly, the component for a semiconductor device fabrication apparatus according to an embodiment has appropriate surface properties and may minimize residues generated during a semiconductor plasma process.

In addition, in the semiconductor device fabrication apparatus according to an embodiment, the focus ring 230 may be omitted. That is, the semiconductor device fabrication apparatus in which the focus ring 230 is omitted may later be equipped with the focus ring 230 separately. In the semiconductor device fabrication apparatus according to an embodiment, the focus ring 230 may be omitted, and the focus ring 230 may be installed later.

Since the focus ring 230 and the upper electrode 220 have the above-described characteristics, the semiconductor device fabrication apparatus according to an embodiment may prevent defects occurring during the process of fabricating the semiconductor substrate 30.

The component for a semiconductor device fabrication apparatus according to an embodiment may include a surface having an Si—OH ratio of approximately 0.16 to approximately 0.28. Since the surface contains an appropriate amount of Si—OH, the inside of the component for a semiconductor device fabrication apparatus according to an embodiment may be effectively protected from external contamination.

In addition, since the surface of the component for a semiconductor device fabrication apparatus according to an embodiment contains Si—OH within the above-described range, external contaminants such as particles may be prevented from adhering to the part.

Accordingly, the component for a semiconductor device fabrication apparatus according to an embodiment may prevent external and internal contamination and prevent contaminants from transferring into the chamber of a semiconductor device fabrication apparatus. Accordingly, the component for a semiconductor device fabrication apparatus according to an embodiment may minimize defects occurred during a semiconductor substrate fabrication process.

In addition, the surface of the component for a semiconductor device fabrication apparatus according to an embodiment may include an appropriate dopant peak. Accordingly, the component for a semiconductor device fabrication apparatus according to an embodiment may have appropriate electrical properties and may minimize defects generated by the dopant.

In addition, the component for a semiconductor device fabrication apparatus according to an embodiment has a surface having a low body-centered cubic ratio and a low rhombohedral ratio. Accordingly, the frequency of crystal defects on the surface of the component for a semiconductor device fabrication apparatus according to an embodiment may be low.

A focus ring according to an embodiment includes appropriate reduced peak valley roughness. An upper electrode and focus ring according to an embodiment may have a surface including a micro-mountain having an appropriate height and a micro-valley having an appropriate depth.

Since the focus ring according to an embodiment includes a surface having an appropriate surface uneven shape, the focus ring can improve plasma flowability on the surface. Accordingly, the focus ring may efficiently guide plasma to the semiconductor substrate.

Accordingly, a semiconductor device fabrication apparatus including the focus ring according to an embodiment may effectively process the surface of the semiconductor substrate.

In addition, since the focus ring according to an embodiment includes a surface having an appropriate surface uneven shape, the focus ring may prevent process residues from being deposited. That is, since the focus ring according to an embodiment has appropriate reduced peak valley roughness, the focus ring may have appropriate irregularities. Accordingly, the contact area between the surface of the focus ring according to an embodiment and process residues may be low. Accordingly, although the process residues are temporarily attached to the surface of the focus ring according to an embodiment, the process residues may be easily detached.

Since the focus ring according to an embodiment includes a surface having a repeating shape of a micro-mountain having an appropriate height and a micro-valley having an appropriate height, the focus ring may improve plasma flowability and inhibit attachment of process residues.

Accordingly, when a plasma process such as a plasma etching process is performed, defects caused by particles generated from the surface of the focus ring according to an embodiment may be easily suppressed. That is, since the focus ring according to an embodiment has an appropriate surface shape, defects that occur when a portion of the micro-mountain of the focus ring falls off may be prevented.

In addition, the features, structures, effects, and the like described in the embodiments above are included in at least one embodiment of the present invention and are not necessarily limited to only one embodiment. In addition, the features, structures, effects, and the like described in each embodiment may be combined or modified by those skilled in the art to which the present disclosure pertains. Therefore, contents related to such combinations and modifications should be construed as being included in the scope of the present disclosure.

The present invention has been described with reference to the embodiments, but the embodiments are merely examples and the present invention is not limited thereto. Those of ordinary skill in the field to which the present disclosure pertains will recognize that various modifications and applications not described above are possible without departing from the essential characteristics of the various embodiments. For example, each component specifically shown in an embodiment may be modified and implemented. These variations and differences in application should be construed as being included in the scope of the present disclosure. Furthermore, the embodiments may be combined to form additional embodiments.

### Manufacturing Example 1

A silicon ingot having a diameter of approximately 300 mm was manufactured by the Czochralski method. The silicon ingot was cut using a diamond wire saw to produce a single-crystal silicon plate having a thickness of approximately 20 mm. Then, the edges of the single-crystal silicon plate were cut to form a chamfer surface.

Then, the single-crystal silicon plate that had been subjected to the chamfering process was placed between an upper surface plate and a lower surface plate and wrapped by the upper surface plate and the lower surface plate. Then, the shape of the wrapped single-crystal silicon plate was machined using a grinder. As a result, a ring having a raw surface was formed.

The shape machining process was performed under the following conditions.
1) Grinder head: 1000 mesh
2) Grinder rotation rate: 6000 rpm
3) Feed: 0.5 mm/minute

Then, the unprocessed ring was immersed in an etchant at room temperature for approximately 7 minutes to treat the outer surface of the unprocessed ring, thereby producing a focus ring.

The ingredients of the etchant are as follows.
1) Deionized water: 34.5%/wt parts by weight
2) Sulfuric acid: 45%/wt parts by weight
3) Ammonium hydrogen fluoride: 8.5%/wt parts by weight
4) Ammonium sulfate: 8.5%/wt parts by weight
5) Ammonium sulfamate: 3.5%/wt parts by weight

The upper surface of the focus ring treated using the etchant was polished.

The conditions of the polishing process are as follows.
1) Polishing pad: DUPONT Co., IC1000
2) Polishing pressure: 200 psi
3) Polishing rotation rate: Upper surface plate: 15 rpm, lower surface plate: 30 rpm
4) Polishing slurry: Silica particles (average particle diameter: 80 nm), pure, weight ratio of 1:3
5) Polishing time: 90 minutes

Then, the focus ring was cleaned using deionized water.

Then, the upper surface, inclined surface, and guide surface of the cleaned focus ring were irradiated with light under atmospheric atmosphere.
1) Light source: White LED
2) Output: 100 W
3) Time: 5 minutes

Immediately, the lower surface of the focus ring was irradiated with light under the same conditions.

Then, the focus ring was sealed.

### Manufacturing Examples 2 to 6

In Table 1 below, the etching time, and whether the polishing process is performed, or the light irradiation conditions were changed from the processes for manufacturing Manufacturing Example 1, are shown. For the remaining processes, the same processes in Manufacturing Example 1 were used.

In Manufacturing Example 5, the etching time was 10 minutes, and the polishing process was performed as in Example 1. In addition, in Manufacturing Example 6, the focus ring that had been subjected to the cleaning process was left at a temperature of approximately 150° C. for approximately 20 minutes under an atmospheric atmosphere.

In Manufacturing Example 6, the etching process, the polishing process, and the light irradiation process were not performed, and the focus ring was sealed immediately after cleaning.

TABLE 1

| | Etching | | | Irradiation |
|---|---|---|---|---|
| | time | Polishing | Output | time |
| Classification | (minutes) | process | (W) | (minutes) |
| Manufacturing | 7 | ◯ | 100 | 5 |
| Example 1 | | | | |
| Manufacturing | 10 | X | 100 | 5 |
| Example 2 | | | | |
| Manufacturing | 13 | X | 150 | 3 |
| Example 3 | | | | |
| Manufacturing | 10 | X | 150 | 3 |
| Example 4 | | | | |
| Manufacturing | 10 | ◯ | — | — |
| Example 5 | | | | |
| Manufacturing | — | X | — | — |
| Example 6 | | | | |

### Manufacturing Example 7

A silicon ingot having a diameter of approximately 300 mm was manufactured by the Czochralski method. The silicon ingot was cut using a diamond wire saw to produce a single-crystal silicon plate having a thickness of approximately 20 mm. Then, the edges of the single-crystal silicon plate were cut to form a chamfer surface.

Then, the single-crystal silicon plate that had been subjected to the chamfering process was placed between an upper surface plate and a lower surface plate and wrapped by the upper surface plate and the lower surface plate. Then, the shape of the wrapped single-crystal silicon plate was machined using a grinder. As a result, a ring having a raw surface was formed.

The shape machining process was performed under the following conditions.
1) Grinder head: 800 mesh
2) Grinder rotation rate: 6000 rpm
3) Feed: 0.7 mm/minute

Then, the unprocessed ring was immersed in an etchant at room temperature for approximately 7 minutes to treat the outer surface of the unprocessed ring, thereby producing a focus ring.

The ingredients of the etchant are as follows.
1) Deionized water: 34.5%/wt parts by weight
2) Sulfuric acid: 40%/wt parts by weight
3) Ammonium hydrogen fluoride: 10%/wt parts by weight
4) Ammonium sulfate: 12%/wt parts by weight
5) Ammonium sulfamate: 3.5%/wt parts by weight

The upper surface of the focus ring treated using the etchant was polished.

The conditions of the polishing process are as follows.
1) Polishing pad: SKC Solmics Co., SR 300
2) Polishing pressure: 300 psi
3) Polishing rotation rate: Upper surface plate: 15 rpm, lower surface plate: 30 rpm
4) Polishing slurry: Silica particles (average particle diameter: 80 nm), pure, weight ratio of 1:3
5) Polishing time: 60 minutes

Then, the focus ring was cleaned using deionized water.

Then, the upper surface, inclined surface, and guide surface of the cleaned focus ring were irradiated with light under atmospheric atmosphere.
1) Light source: White LED
2) Output: 80 W
3) Time: 7 minutes Immediately, the lower surface of the focus ring was irradiated with light under the same conditions.

Then, the focus ring was sealed.

### Manufacturing Examples 8 to 10

In Table 2 below, the etching time, and whether the polishing process is performed, or the light irradiation conditions were changed from the processes for manufacturing Manufacturing Example 7, are shown. For the remaining processes, the same processes in Manufacturing Example 7 were used.

TABLE 2

| | Etching | | | Irradiation |
|---|---|---|---|---|
| | time | Polishing | Output | time |
| Classification | (minutes) | process | (W) | (minutes) |
| Manufacturing | 7 | ◯ | 80 | 7 |
| Example 7 | | | | |
| Manufacturing | 7 | X | 80 | 7 |
| Example 8 | | | | |
| Manufacturing | 10 | X | 100 | 4 |
| Example 9 | | | | |
| Manufacturing | 7 | X | 100 | 4 |
| Example 10 | | | | |

In Manufacturing Example 11, the etching process, the polishing process, and the light irradiation process were not performed, and the focus ring was sealed immediately after cleaning.

In Manufacturing Example 12, the etching process, the polishing process, and the light irradiation process were not performed. After cleaning of the focus ring was completed, the cleaned focus ring was heat-treated at a temperature of approximately 200° C. for approximately 3 minutes under atmospheric atmosphere.

### Manufacturing Example 13

A silicon ingot having a diameter of approximately 300 mm was manufactured by the Czochralski method. The silicon ingot was cut using a diamond wire saw to produce a single-crystal silicon plate having a thickness of approximately 20 mm. Then, the edges of the single-crystal silicon plate were cut to form a chamfer surface.

Then, the single-crystal silicon plate that had been subjected to the chamfering process was placed between an upper surface plate and a lower surface plate and wrapped by the upper surface plate and the lower surface plate. Then, the shape of the wrapped single-crystal silicon plate was machined using a grinder. As a result, a ring having a raw surface was formed.

The shape machining process was performed under the following conditions.
1) Grinder head: 1100 mesh
2) Grinder rotation rate: 6100 rpm
3) Feed: 0.6 mm/minute

Then, the unprocessed ring was immersed in an etchant at room temperature for approximately 6 minutes to treat the outer surface of the unprocessed ring, thereby producing a focus ring.

The ingredients of the etchant are as follows.
1) Deionized water: 34.5%/wt parts by weight
2) Sulfuric acid: 40%/wt parts by weight
3) Ammonium hydrogen fluoride: 10%/wt parts by weight
4) Ammonium sulfate: 12%/wt parts by weight
5) Ammonium sulfamate: 3.5%/wt parts by weight

The upper surface of the focus ring treated using the etchant was polished.

The conditions of the polishing process are as follows.
1) Polishing pad: SKC Solmics Co., SR 300
2) Polishing pressure: 300 psi
3) Polishing rotation rate: Upper surface plate: 15 rpm, lower surface plate: 30 rpm
4) Polishing slurry: Silica particles (average particle diameter: 80 nm), pure, weight ratio of 1:3
5) Polishing time: 60 minutes

Then, the focus ring was cleaned using deionized water.

Then, the focus ring was sealed.

### Manufacturing Examples 14 to 17

As shown in Table 3 below, the etching time and the polishing time were changed from the processes for manufacturing Manufacturing Example 13. For the remaining processes, the same processes in Manufacturing Example 13 were used.

### Manufacturing Example 18

As shown in Table 3 below, the etching time, the polishing time, and the conditions described below were change from the processes for manufacturing Manufacturing Example 13. For the remaining processes, the same processes in Manufacturing Example 13 were used.
1) Polishing pad: SKC Solmics Co., SR 300
2) Polishing pressure: 200 psi
3) Polishing rotation rate: Upper surface plate: 15 rpm, lower surface plate: 30 rpm
4) Polishing slurry: Silica particles (average particle diameter: 40 nm), pure, weight ratio of 1:3
5) Polishing time: 90 minutes

TABLE 3

| | Etching time | Polishing time |
|---|---|---|
| Classification | (minutes) | (minutes) |
| Manufacturing | 6 | 60 |
| Example 13 | | |
| Manufacturing | 8 | 20 |
| Example 14 | | |
| Manufacturing | 8 | 0 |
| Example 15 | | |
| Manufacturing | 5 | 0 |
| Example 16 | | |
| Manufacturing | 1 | — |
| Example 17 | | |
| Manufacturing | 8 | 90 |
| Example 18 | | |

### Examples 1 to 13 and Comparative Examples 1 to 5

As shown in Table 4 below, a focus ring was mounted on a wafer etching device, and a silicon wafer was placed on the etching device. Then, hydrogen gas, nitrogen gas, and CH₃F were sprayed onto an upper electrode at a flow ratio of approximately 5:1:0.5, turned into plasma, and sprayed on the silicon wafer for approximately 10 minutes to proceed with an etching process.

TABLE 4

| Classification | Focus ring |
|---|---|
| Example 1 | Manufacturing Example 1 |
| Example 2 | Manufacturing Example 2 |
| Example 3 | Manufacturing Example 3 |
| Example 4 | Manufacturing Example 4 |
| Comparative Example 1 | Manufacturing Example 5 |
| Comparative Example 2 | Manufacturing Example 6 |
| Example 5 | Manufacturing Example 7 |
| Example 6 | Manufacturing Example 8 |
| Example 7 | Manufacturing Example 9 |
| Example 8 | Manufacturing Example 10 |
| Comparative Example 3 | Manufacturing Example 11 |
| Comparative Example 4 | Manufacturing Example 12 |
| Example 9 | Manufacturing Example 13 |
| Example 10 | Manufacturing Example 14 |
| Example 11 | Manufacturing Example 15 |
| Example 12 | Manufacturing Example 16 |
| Example 13 | Manufacturing Example 17 |
| Comparative Example 5 | Manufacturing Example 18 |

### Evaluation Example

1. Water Contact Angle, Diiodomethane Contact Angle, Dispersion Free Energy, Polar Free Energy, and Surface Free Energy

The focus rings manufactured in Examples and Comparative Examples were mounted on a mobile surface analyzer (MSA) (KRUSS Co.). Then, according to the following measurement conditions, a water contact angle, a diiodomethane contact angle and dispersion free energy, polar free energy, and surface free energy calculated by the geometric mean combining rule (OWRK method) were measured at the surfaces. The same measurement was repeated five times, and the average value of three measurements excluding the upper and lower limits was calculated.
Measurement time: 2 seconds
Volumetric capacity. 1 μL

2. Raman Spectrum

A Raman spectrum was measured using a micro Raman spectroscope (Jobin Yvon Spex T64000) having a resolution of 1 μm. The area of each peak was automatically calculated by a program built into the micro Raman spectroscope.

The conditions for measuring the Raman spectrum are as follows.
Laser source: Ar ion laser having a wavelength of 514.532 nm
Power: 3.9 mW
Exposure time: 100 Hz
#Scan: 70
Lens: ×100 WD
2.5 μm Confocal pinhole

3. 3D Surface Illumination

(1) Sampling & Pretreatment Methods

Storage/pretreatment conditions: The prepared samples were stored at 20° C. and 30 RH % for 24 hours. The samples were measured immediately upon removal from the storage device.
Sample size: 5 cm×5 cm
Measurement area: 5 random points within 1 cm from the edge

(2) Evaluation Methods

3D roughness was calculated by measuring a material ratio using a measuring device. 3D roughness was measured using a non-contact 3D roughness measuring device (3D optical microscopy, model: Contour GT, Bruker Co.) in a vertical scanning interferometry (VSI) mode. When setting measurement magnification, the eyepiece was set to 1.0× (multiply), the objective lens was set to 20× (objective lens×eyepiece=measurement magnification), and the measured result value was calculated. Then, the measured values were corrected once by applying a Gaussian filter, and then surface roughness parameters (e.g., Sz, etc.) were obtained using the calculation formula defined in the ISO 25178-2 standard. The data was recorded by calculating the average of 3 areas after excluding the maximum and minimum values measured in a total of 5 areas.

4. Defect Evaluation

Using a wafer surface analyzer (WM-3000, Zeus Co.), the number of defects in the etched silicon wafer was measured.

When the number of defects is 5 or less: Excellent, ⊚

When the number of defects is 6 to 10: Good, ∘

When the number of defects is 11 or more: Poor, x

5. Residual Organic Matter Evaluation

After performing the etching process, residues remaining in the surface of the focus ring were measured using an energy dispersive x-ray spectrometer (EDS).

When the carbon content of the total elements of the surface is 10% or less; Good, O

When the carbon content of the total elements of the surface exceeds 10%: Poor, X

As shown in Table 5 below, a water contact angle, a diiodomethane contact angle, dispersion free energy, polar free energy, and surface free energy were measured at the upper surface of a body portion.

TABLE 5

| | Water contact | Diiodomethane | Dispersion | Polar free | Surface free |
|---|---|---|---|---|---|
| | angle | contact angle | free energy | energy | energy |
| Classification | (°) | (°) | (mN/m) | (mN/m) | (mN/m) |
| Manufacturing | 69 | 48 | 35.9 | 9.4 | 45.3 |
| Example 1 | | | | | |
| Manufacturing | 57 | 52 | 32.2 | 18.1 | 50.3 |
| Example 2 | | | | | |
| Manufacturing | 55 | 47 | 35.8 | 17.0 | 52.8 |
| Example 3 | | | | | |
| Manufacturing | 52 | 43 | 38.1 | 18.9 | 57.0 |
| Example 4 | | | | | |
| Manufacturing | 35 | 59 | 46.3 | 19.0 | 65.3 |
| Example 5 | | | | | |
| Manufacturing | 76 | 40.35 | 30.2 | 8.5 | 38.7 |
| Example 6 | | | | | |

As shown in Table 6 below, a water contact angle, a diiodomethane contact angle, dispersion free energy, polar free energy, and surface free energy were measured at the inclined surface of an inclined portion.

TABLE 6

| | Water contact | Diiodomethane | Dispersion | Polar free | Surface free |
|---|---|---|---|---|---|
| | angle | contact angle | free energy | energy | energy |
| Classification | (°) | (°) | (mN/m) | (mN/m) | (mN/m) |
| Manufacturing | 65 | 51 | 34.7 | 10.8 | 45.5 |
| Example 1 | | | | | |
| Manufacturing | 56 | 53 | 33.3 | 18.2 | 51.5 |
| Example 2 | | | | | |
| Manufacturing | 54 | 47 | 36.2 | 16.0 | 52.2 |
| Example 3 | | | | | |
| Manufacturing | 53 | 42 | 37.4 | 17.5 | 54.9 |
| Example 4 | | | | | |
| Manufacturing | 36 | 59 | 45.2 | 18.9 | 64.1 |
| Example 5 | | | | | |
| Manufacturing | 76 | 40.6 | 31.3 | 8.7 | 40.0 |
| Example 6 | | | | | |

As shown in Table 7 below, a water contact angle, a diiodomethane contact angle, dispersion free energy, polar free energy, and surface free energy were measured at the guide surface of a guide portion.

TABLE 7

| | Water contact | Diiodomethane | Dispersion | Polar free | Surface free |
|---|---|---|---|---|---|
| | angle | contact angle | free energy | energy | energy |
| Classification | (°) | (°) | (mN/m) | (mN/m) | (mN/m) |
| Manufacturing | 67 | 48 | 36.5 | 10.3 | 46.8 |
| Example 1 | | | | | |
| Manufacturing | 57 | 53 | 34.1 | 16.6 | 50.7 |
| Example 2 | | | | | |
| Manufacturing | 55 | 48 | 35.2 | 17.5 | 52.7 |
| Example 3 | | | | | |
| Manufacturing | 53 | 45 | 37.3 | 17.2 | 54.5 |
| Example 4 | | | | | |
| Manufacturing | 32 | 58.5 | 43.2 | 20.1 | 63.3 |
| Example 5 | | | | | |
| Manufacturing | 75 | 40.9 | 30.5 | 8.7 | 39.2 |
| Example 6 | | | | | |

As shown in Table 8 below, a water contact angle, a diiodomethane contact angle, dispersion free energy, polar free energy, and surface free energy were measured at a lower surface.

TABLE 8

| | Water contact | Diiodomethane | Dispersion | Polar free | Surface free |
|---|---|---|---|---|---|
| | angle | contact angle | free energy | energy | energy |
| Classification | (°) | (°) | (mN/m) | (mN/m) | (mN/m) |
| Manufacturing | 69 | 49 | 35.8 | 9.7 | 45.3 |
| Example 1 | | | | | |
| Manufacturing | 57 | 53 | 33.2 | 17.5 | 50.8 |
| Example 2 | | | | | |
| Manufacturing | 55 | 59 | 34.9 | 17.0 | 51.9 |
| Example 3 | | | | | |
| Manufacturing | 52 | 44 | 38.2 | 18.7 | 56.9 |
| Example 4 | | | | | |
| Manufacturing | 29 | 58.9 | 44.2 | 19.8 | 64.0 |
| Example 5 | | | | | |
| Manufacturing | 75 | 40.55 | 30.5 | 8.9 | 39.4 |
| Example 6 | | | | | |

As shown in Table 9 below, in the case of the methods of fabricating a semiconductor device according to Examples 1 to 4, the number of defects and the residue content were reduced.

TABLE 9

| Classification | Defects | Residues |
|---|---|---|
| Example 1 | ⊚ | ◯ |
| Example 2 | ⊚ | ◯ |
| Example 3 | ⊚ | ◯ |
| Example 4 | ⊚ | ◯ |
| Comparative Example 1 | X | X |
| Comparative Example 2 | X | X |

As shown in Tables 5 to 9, the focus rings according to Examples had appropriate surface properties. In addition, in the case of the methods of fabricating a semiconductor device according to Examples, the number of defects and the residue content were reduced.

As shown in Table 10 below, the area of each peak according to Raman shift was measured on the upper surface of the body portion.

TABLE 10

| | | | | | 940~980 |
|---|---|---|---|---|---|
| Classification | 304 cm⁻¹ | 349 cm⁻¹ | 434 cm⁻¹ | 521 cm⁻¹ | cm⁻¹ |
| Manufacturing | 1138 | 20 | 35 | 16904 | 3803 |
| Example 7 | | | | | |
| Manufacturing | 1541 | 11 | 23 | 24206 | 4912 |
| Example 8 | | | | | |
| Manufacturing | 2269 | 41 | 27 | 23620 | 5561 |
| Example 9 | | | | | |
| Manufacturing | 2349 | 24 | 23 | 28421 | 5879 |
| Example 10 | | | | | |
| Manufacturing | 2176 | 333 | 226 | 23178 | 3225 |
| Example 11 | | | | | |
| Manufacturing | 1531 | 153 | 133 | 22357 | 6853 |
| Example 12 | | | | | |

As shown in Table 11 below, the area of each peak according to Raman shift was measured on the inclined surface of the inclined portion.

TABLE 11

| | | | | | 940~980 |
|---|---|---|---|---|---|
| Classification | 304 cm⁻¹ | 349 cm⁻¹ | 434 cm⁻¹ | 521 cm⁻¹ | cm⁻¹ |
| Manufacturing | 1644 | 23 | 35 | 16880 | 3822 |
| Example 7 | | | | | |
| Manufacturing | 1486 | 27 | 36 | 24206 | 4912 |
| Example 8 | | | | | |
| Manufacturing | 2412 | 17 | 16 | 22593 | 5820 |
| Example 9 | | | | | |
| Manufacturing | 1984 | 32 | 21 | 25818 | 5192 |
| Example 10 | | | | | |
| Manufacturing | 2157 | 259 | 234 | 23189 | 3150 |
| Example 11 | | | | | |
| Manufacturing | 1423 | 162 | 153 | 22517 | 6705 |
| Example 12 | | | | | |

As shown in Table 12 below, the area of each peak according to Raman shift was measured on the guide surface of the guide portion.

TABLE 12

| | | | | | 940~980 |
|---|---|---|---|---|---|
| Classification | 304 cm⁻¹ | 349 cm⁻¹ | 434 cm⁻¹ | 521 cm⁻¹ | cm⁻¹ |
| Manufacturing | 1513 | 11 | 15 | 17512 | 4023 |
| Example 7 | | | | | |
| Manufacturing | 1578 | 16 | 14 | 22306 | 4817 |
| Example 8 | | | | | |
| Manufacturing | 2322 | 51 | 33 | 22678 | 5678 |
| Example 9 | | | | | |
| Manufacturing | 1963 | 11 | 22 | 24597 | 5595 |
| Example 10 | | | | | |
| Manufacturing | 2133 | 265 | 233 | 22975 | 3021 |
| Example 11 | | | | | |
| Manufacturing | 1561 | 152 | 168 | 22654 | 6789 |
| Example 12 | | | | | |

As shown in Table 13 below, the area of each peak according to Raman shift was measured on the lower surface.

TABLE 13

| | | | | | 940~980 |
|---|---|---|---|---|---|
| Classification | 304 cm⁻¹ | 349 cm⁻¹ | 434 cm⁻¹ | 521 cm⁻¹ | cm⁻¹ |
| Manufacturing | 1354 | 36 | 22 | 17123 | 3968 |
| Example 7 | | | | | |
| Manufacturing | 1522 | 33 | 57 | 22647 | 4789 |
| Example 8 | | | | | |
| Manufacturing | 2235 | 19 | 18 | 23023 | 5541 |
| Example 9 | | | | | |
| Manufacturing | 2231 | 17 | 22 | 25016 | 5691 |
| Example 10 | | | | | |
| Manufacturing | 2111 | 205 | 241 | 22957 | 3033 |
| Example 11 | | | | | |
| Manufacturing | 1601 | 133 | 169 | 23001 | 6811 |
| Example 12 | | | | | |

As shown in Table 14 below, in the case of the semiconductor devices fabricated according to Examples 5 to 8, the number of defects and the residue content were reduced.

TABLE 14

| Classification | Defects | Residues |
|---|---|---|
| Example 5 | ⊚ | ◯ |
| Example 6 | ⊚ | ◯ |
| Example 7 | ⊚ | ◯ |
| Example 8 | ⊚ | ◯ |
| Comparative Example 3 | X | X |
| Comparative Example 4 | X | X |

As shown in Tables 10 to 14, in the case of the methods of fabricating a semiconductor device according to Examples, the number of defects and the residue content were reduced.

As shown in Table 15 below, the roughness of the upper surface of the body portion was measured.

TABLE 15

| | Sk | Spk | Svk | Sv | Sz | Sp |
|---|---|---|---|---|---|---|
| Classification | (μm) | (μm) | (μm) | (μm) | (μm) | (μm) |
| Manufacturing | 0.018 | 0.0058 | 0.0095 | −0.303 | 0.355 | 0.052 |
| Example 13 | | | | | | |
| Manufacturing | 0.404 | 0.0006 | 0.007 | −1.112 | 2.29 | 1.178 |
| Example 14 | | | | | | |
| Manufacturing | 1.735 | 0.4499 | 0.9044 | −2.121 | 4.616 | 2.495 |
| Example 15 | | | | | | |
| Manufacturing | 1.403 | 0.426 | 0.9044 | −2.102 | 4.288 | 2.186 |
| Example 16 | | | | | | |
| Manufacturing | 0.005 | 0.0023 | 0.0045 | −0.163 | 0.210 | 0.023 |
| Example 17 | | | | | | |
| Manufacturing | 2.956 | 1.121 | 1.356 | −3.05 | 5.361 | 3.570 |
| Example 18 | | | | | | |

As shown in Table 16 below, the roughness of the inclined surface of the inclined portion was measured.

TABLE 16

| | Sk | Spk | Svk | Sv | Sz | Sp |
|---|---|---|---|---|---|---|
| Classification | (μm) | (μm) | (μm) | (μm) | (μm) | (μm) |
| Manufacturing | 0.016 | 0.0059 | 0.0065 | −0.041 | 0.136 | 0.095 |
| Example 13 | | | | | | |
| Manufacturing | 0.421 | 0.4499 | 0.9586 | −1.101 | 2.353 | 1.252 |
| Example 14 | | | | | | |
| Manufacturing | 2.081 | 0.4544 | 0.9586 | −2.13 | 4.714 | 2.504 |
| Example 15 | | | | | | |
| Manufacturing | 1.355 | 0.4018 | 0.911 | −2.125 | 4.217 | 2.092 |
| Example 16 | | | | | | |
| Manufacturing | 0.006 | 0.0024 | 0.0047 | −0.201 | 0.231 | 0.026 |
| Example 17 | | | | | | |
| Manufacturing | 2.876 | 1.035 | 1.125 | −3.23 | 5.214 | 3.247 |
| Example 18 | | | | | | |

As shown in Table 17 below, the roughness of the guide surface of the guide portion was measured.

TABLE 17

| | Sk | Spk | Svk | Sv | Sz | Sp |
|---|---|---|---|---|---|---|
| Classification | (μm) | (μm) | (μm) | (μm) | (μm) | (μm) |
| Manufacturing | 0.015 | 0.0051 | 0.0055 | −0.028 | 0.056 | 0.028 |
| Example 13 | | | | | | |
| Manufacturing | 0.42 | 0.4444 | 0.8691 | −1.205 | 2.367 | 1.161 |
| Example 14 | | | | | | |
| Manufacturing | 1.693 | 0.3841 | 0.8691 | −2111 | 4.46 | 2.35 |
| Example 15 | | | | | | |
| Manufacturing | 1.152 | 0.3618 | 0.7144 | −2.084 | 4.036 | 1.952 |
| Example 16 | | | | | | |
| Manufacturing | 0.007 | 0.0031 | 0.0046 | −2.11 | 0.241 | 0.028 |
| Example 17 | | | | | | |
| Manufacturing | 2.785 | 1.126 | 1.125 | −3.335 | 5.114 | 3.256 |
| Example 18 | | | | | | |

As shown in Table 18 below, the roughness of the lower surface of the body portion was measured.

TABLE 18

| | Sk | Spk | Svk | Sv | Sz | Sp |
|---|---|---|---|---|---|---|
| Classification | (μm) | (μm) | (μm) | (μm) | (μm) | (μm) |
| Manufacturing | 0.028 | 0.0061 | 0.0011 | −0.313 | 0.305 | 0.072 |
| Example 13 | | | | | | |
| Manufacturing | 0.414 | 0.0016 | 0.0086 | −1.132 | 2.331 | 1.180 |
| Example 14 | | | | | | |
| Manufacturing | 1.715 | 0.4400 | 0.9144 | −2.221 | 4.615 | 2.425 |
| Example 15 | | | | | | |
| Manufacturing | 1.413 | 0.427 | 0.9011 | −2.133 | 4.226 | 2.196 |
| Example 16 | | | | | | |
| Manufacturing | 0.004 | 0.0021 | 0.0042 | −0.162 | 0.209 | 0.023 |
| Example 17 | | | | | | |
| Manufacturing | 2.989 | 1.126 | 1.357 | −3.091 | 5.363 | 3.170 |
| Example 18 | | | | | | |

As shown in Table 19 below, in Examples 9 to 13 and Comparative Example 5, the number of defects and the residue content were calculated.

TABLE 19

| Classification | Defects | Residues |
|---|---|---|
| Example 9 | ◯ | ◯ |
| Example 10 | ◯ | ◯ |
| Example 11 | ⊚ | ◯ |
| Example 12 | ⊚ | ◯ |
| Example 13 | ◯ | X |
| Comparative Example 5 | X | X |

As shown in Tables 15 to 19, the focus rings according to Examples suppressed defects and reduced the content of residues.

What is claimed is:

1. A component for a semiconductor device fabrication apparatus, the component comprising single-crystal silicon,
wherein, on at least one surface thereof, a water contact angle is 45° to 74° and a diiodomethane contact angle is 41° to 57°.

2. The component according to claim 1, wherein a surface free energy of the surface is 40 mN/m to 65 mN/m.

3. The component according to claim 2, wherein a dispersion free energy of the surface is 30 mN/m to 45 mN/m.

4. The component according to claim 3, wherein a polar free energy of the surface is 5 mN/m to 25 mN/m.

5. The component according to claim 1, further comprising:
a body portion formed to surround a semiconductor substrate;
an inclined portion formed to extend from the body portion toward a center of the semiconductor substrate; and
a guide portion formed to extend from the inclined portion toward a center of the semiconductor substrate and disposed below the semiconductor substrate,
wherein the body portion comprises an upper surface; and a lower surface facing the upper surface, and
wherein, on the upper surface, a water contact angle is 45° to 74° and a diiodomethane contact angle is 41° to 57°.

6. The component according to claim 5, wherein the inclined portion comprises an inclined surface extending from the upper surface in a direction inclined with respect to the upper surface, and
wherein, on the inclined surface, a water contact angle is 45° to 74° and a diiodomethane contact angle is 41° to 57°.

7. The component according to claim 6, wherein the guide portion comprises a guide surface extending from the inclined surface, and
wherein, on the guide surface, a water contact angle is 45° to 74° and a diiodomethane contact angle is 41° to 57°.

8. The component according to claim 1, wherein, on 70% or more of the total surface, a water contact angle is 45° to 74° and a diiodomethane contact angle is 41° to 57°.

9. The component according to claim 5, wherein the body portion, the inclined portion, and the guide portion are integrally formed of single-crystal silicon.

10. The component according to claim 5, wherein a surface free energy of the upper surface is 40 mN/m to 65 mN/m.

11. The component according to claim 1, further comprising:
an upper surface;
a lower surface facing the upper surface; and
through-holes formed to penetrate from the upper surface to the lower surface,
wherein, on the lower surface, a water contact angle is 45° to 74° and a diiodomethane contact angle is 41° to 57°.

12. The component according to claim 5, wherein, on the upper surface, a first reduced peak valley roughness is 0.005 μm to 2 μm, and
wherein the first reduced peak valley roughness is a sum of a first average height of peaks above a core surface (Spk) roughness of the upper surface and a first average depth of valleys below a core surface (Svk) roughness of the upper surface.

13. The component according to claim 1, wherein an Si—OH ratio on at least one surface thereof is 0.16 to 0.28,
wherein the Si—OH ratio is a value obtained by dividing an area of an Si—OH peak by an area of an Si single-crystal peak in a Raman spectrum of the surface,
the Si single-crystal peak is a peak at a Raman shift of 520 cm⁻¹ to 522 cm⁻¹ in the Raman spectrum of the surface, and
the Si—OH peak is a peak at a Raman shift of 940 cm⁻¹ to 980 cm⁻¹ in the Raman spectrum of the surface.

14. A semiconductor device fabrication apparatus comprising:
a chamber for accommodating a semiconductor substrate;
an upper electrode that is disposed inside the chamber opposite the semiconductor substrate, and sprays a process gas;
an electrostatic chuck configured to support the semiconductor substrate and disposed below the semiconductor substrate; and
a focus ring formed to surround the semiconductor substrate and disposed on the electrostatic chuck,
wherein, on at least one surface of the focus ring or upper electrode, a water contact angle is 45° to 74° and a diiodomethane contact angle is 41° to 57°.

15. The semiconductor device fabrication apparatus according to claim 14, wherein the focus ring comprises a body portion formed to surround a semiconductor substrate;
an inclined portion formed to extend from the body portion toward a center of the semiconductor substrate; and
a guide portion formed to extend from the inclined portion toward a center of the semiconductor substrate and disposed below the semiconductor substrate,
wherein the body portion comprises an upper surface; and a lower surface facing the upper surface, and
wherein, on the upper surface, a water contact angle is 45° to 74° and a diiodomethane contact angle is 41° to 57°.

16. The semiconductor device fabrication apparatus according to claim 15, wherein, on the upper surface, a first reduced peak valley roughness is 0.005 μm to 2 μm, and
wherein the first reduced peak valley roughness is a sum of a first Spk roughness of the upper surface and a first Svk roughness of the upper surface.

17. A semiconductor device fabrication apparatus according to claim 15, wherein, on at least one surface of the focus ring or upper electrode, an Si—OH ratio is 0.16 to 0.28, and
wherein the Si—OH ratio is a value obtained by dividing an area of an Si—OH peak by an area of an Si single-crystal peak in a Raman spectrum of the surface,
the Si single-crystal peak is a peak at a Raman shift of 520 cm⁻¹ to 522 cm⁻¹ in the Raman spectrum of the surface, and
the Si—OH peak is a peak at a Raman shift of 940 cm⁻¹ to 980 cm⁻¹ in the Raman spectrum of the surface.

18. A method of fabricating a semiconductor device, the method comprising:
placing a semiconductor substrate on a semiconductor device fabrication apparatus; and
treating the semiconductor substrate,
wherein the semiconductor device fabrication apparatus comprises a chamber for accommodating the semiconductor substrate;
an upper electrode disposed inside the chamber opposite the semiconductor substrate and sprays a process gas;
an electrostatic chuck configured to support the semiconductor substrate and disposed below the semiconductor substrate; and
a focus ring formed to surround the semiconductor substrate and disposed on the electrostatic chuck,
wherein, on at least one surface of the upper electrode and focus ring, a water contact angle is 45° to 74° and a diiodomethane contact angle is 41° to 57°.

19. The method according to claim 18, wherein the focus ring comprises a body portion formed to surround a semiconductor substrate;
an inclined portion formed to extend from the body portion toward a center of the semiconductor substrate; and
a guide portion formed to extend from the inclined portion toward a center of the semiconductor substrate and disposed below the semiconductor substrate,
wherein the body portion comprises an upper surface; and a lower surface facing the upper surface,
wherein, on the upper surface, a water contact angle is 45° to 74° and a diiodomethane contact angle is 41° to 57°.

20. The method according to claim 19, wherein, on the upper surface, a first reduced peak valley roughness is 0.005 μm to 2 μm, and
wherein the first reduced peak valley roughness is a sum of a first Spk roughness of the upper surface and a first Svk roughness of the upper surface.
